(19) United States
(12) Patent Application Publication
(10) Pub. No.: US 2026/0267230 A1
(43) Pub. Date: Sep. 10, 2026

(54) SHORT-WAVE SYSTEMS AND METHODS AND SUITABLE TARGETS THEREOF

(71) Applicant: L2X-LABS LTD, Jerusalem (IL)

(72) Inventors: Evgeny PAPEER, Jerusalem (IL); Yechiel Refael FRANK, Zur-Hadassah (IL)

(73) Assignee: L2X-LABS LTD, Jerusalem (IL)

(21) Appl. No.: 19/165,783

(22) PCT Filed: Mar. 26, 2024
(86) PCT No.: PCT/IL2024/050307

§ 371 Date: Sep. 16, 2025

(30) Foreign Application Priority Data
Mar. 27, 2023 (IL) 301730

(51) Int. Cl. G03F 7/00

(52) U.S. Cl. CPC G03F 7/70025; G03F 7/70891; G03F 7/7005

(57) ABSTRACT

A short-wave radiation system, comprising: (a) at least one light source, collectively operable to continuously emit light for a continuous lighting duration that is at least 500 nanoseconds long toward a continuous ionization target that is moving with respect to the at least one light source, thereby gradually ionizing during the continuous lighting duration a continuous area of the continuous ionization target in a continuous manner, resulting in emittance by ionized parts of the continuous ionization target of continuous short-wave radiation during the continuous lighting duration; wherein the continuous area of the continuous ionization target is at least one order of magnitude larger than an illuminated area projected by the at least one light source on the continuous ionization target at any given moment during the continuous lighting duration; and (b) optics, for directing the continuous short-wave radiation toward a designated beam direction of the short-wave radiation system.

### RELATED APPLICATIONS

This application claims priority from Israel patent application serial number 301,730, filing date Mar. 27, 2023.

### FIELD

The invention related to short-wave systems and methods, and especially to extreme ultraviolet (EUV) systems and methods. Such systems and method may pertain to short-wave based technology (e.g., lithography and EUV inspection machines, systems, and methods) and especially to short-wave light sources utilized for such short-wave systems and methods.

### BACKGROUND

Short-wave Radiation (SWR), i.e., radiation having a wavelength shorter than 200 nm, has a wide range of applications in fields such as lithography, material processing, and medical treatment. In particular, the use of UV radiation in lithography has become increasingly important in the semiconductor industry, where it is used to pattern photoresist and other materials with high precision. However, conventional SWR light sources often suffer from limited power and stability, which can limit their usefulness in industrial applications. There is therefore a need for a new and improved light source that can generate and emit SWR radiation with high power and stability, making it suitable for use in a variety of applications, such as lithography and material processing.

Ionizing radiation is a type of electromagnetic radiation that has sufficient energy to remove tightly bound electrons from atoms, a process known as ionization. Ionizing radiation is found in several sources, including nuclear reactions, radioactive decay, and high-energy particle accelerators. In recent years, there has been increasing interest in using ionizing radiation, specifically extreme ultraviolet (EUV) light, as a source for lithography, a process used in the manufacturing of microchips and other electronic devices. Lithography involves using light to transfer a pattern onto a substrate, such as a silicon wafer, and EUV light has the potential to significantly improve the resolution and accuracy of this process.

Extreme ultraviolet (EUV) light is a type of electromagnetic SWR. While the exact definitions used by different scientist may vary, within the context of this disclosure the term EUV pertains to a spectral range which includes at least the electromagnetic radiation with wavelengths ranging from 10-120 nm. EUV light is difficult to generate and requires specialized equipment, making it challenging to produce on high volume manufacturing condition which require high output power of the EUV system and efficient conversion of electricity power to outputted EUV (the same is also true more generally for SWR systems). There are several different approaches to generating EUV light, including plasma-based and laser-based methods, and researchers are actively working to develop more efficient and cost-effective ways of producing EUV light for use in lithography and other applications.

U.S. Pat. No. 10/588,210 by Vinokhodov, Aleksandr Yurievich, et al., published on Mar. 10, 2020 and entitled “High Brightness Short-Wavelength Radiation Source (Variants)” discusses a high-brightness short-wavelength radiation source that contains a vacuum chamber with a rotating target assembly having an annular groove, an energy beam of a pulsed laser beam focused on the target, a useful short-wavelength radiation beam coming out of the interaction zone, wherein the target is a layer of molten metal formed by a centrifugal force on a surface of the annular groove facing a rotation axis. A replaceable membrane made of carbon nanotubes may be installed on a pathway of the short-wavelength radiation beam for debris mitigation. Parameters such as laser pulse repetition rate are chosen in order to suppress debris. In other embodiments the energy beam is the electron beam produced by an electron gun and the rotating target assembly is a rotating anode.

U.S. Pat. No. 10/887,973 by Ivanov, Vladimir Vitalievich, et al., published on Jan. 5, 2021, and entitled “High Brightness Laser-Produced Plasma Light Source” discusses a laser-produced plasma light source which contains a vacuum chamber with a rotating target assembly providing a target in an interaction zone with a laser beam focused on the said target, which is a molten metal layer. A debris shield is rigidly mounted to surround the interaction zone, said shield comprising only two opening forming an entrance for the laser beam and an exit for a short-wavelength radiation beam. The means for debris mitigation can additionally include: the rotation of target with high linear velocity exciding 80 m/s; the orientation of the short-wavelength radiation beam and/or of the laser beam at an angle of less than 45° to the target surface, a nozzle supplying a high-speed gas flow to the interaction zone, etc. The technical result is the creation of the high-brightness low-debris sources of soft X-ray, EUV and VUV light at wavelengths of 0.4 to 200 nm.

U.S. Pat. No. 11/252,810 by Ivanov, Vladimir Vitalievich, et al., published on Feb. 15, 2022 and entitled “Short-Wavelength Radiation Source with Multisectional Collector Module and Method of Collecting Radiation” discusses a radiation source that contains a collector module comprising an optical collector, positioned in a vacuum chamber with an emitting plasma, further comprising a means for debris mitigation which include at least two casings arranged to output debris-free homocentric beams of the short-wavelength radiation, coming to the optical collector preferably consisting of several identical mirrors. Outside each casing there are permanent magnets that create a magnetic field inside the casings to mitigate charged fraction of debris particles and provide the debris-free homocentric beams of short-wavelength radiation. Other debris mitigating techniques are additionally used. Preferably the plasma is laser-produced plasma of a liquid metal target supplied by a rotating target assembly to a focus area of a laser beam. The technical result of the invention is the creation of high-powerful high-brightness debris-free sources of short-wavelength radiation with large, preferably more than 0.25 sr, collection solid angle.

United States patent application publication serial number US 2015/0076359 by Bykanov, Alexander, et al., filing date 18 Jul., 2014 and entitled “System and Method for Generation of Extreme Ultraviolet Light” discusses an EUV light source includes a rotatable, cylindrically-symmetric element having a surface coated with a plasma-forming target material, a drive laser source configured to generate one or more laser pulses sufficient to generate EUV light via formation of a plasma by excitation of the plasma-forming target material, a set of focusing optics configured to focus the one or more laser pulses onto the surface of the rotatable, cylindrically-symmetric element, a set of collection optics configured to receive EUV light emanated from the generated plasma and further configured to direct the illumination to an intermediate focal point, and a gas management system including a gas supply subsystem configured to supply plasma-forming target material to the surface of the rotatable, cylindrically-symmetric element.

Limitations and disadvantages of conventional, traditional, and proposed approaches will become apparent to one of skill in the art, through comparison of such approaches with the subject matter of the present application as set forth in the remainder of the present application with reference to the drawings.

### General Description

According to a broad aspect of the invention, there is disclosed a Short wave Radiation (SWR) system, which includes: (i) at least one light source, collectively operable to continuously emit light for a continuous lighting duration (CLD) that is at least 500 nanoseconds long toward a continuous ionization target (CIT) that is moving with respect to the at least one light source, thereby gradually ionizing during the CLD a continuous area of the CIT in a continuous manner, resulting in emittance by ionized parts of the CIT of continuous SWR during the CLD; wherein the continuous area of the CIT is at least one order of magnitude larger than an illuminated area projected by the at least one light source on the CIT at any given moment during the CLD; and (ii) optics, for directing the continuous SWR toward a designated beam direction of the SWR system.

According to a further aspect of the invention, the continuous area of the CIT may be at least 10,000 μm².

According to a further aspect of the invention, each light source out of the at least one light source may be a multi-Kilowatt class solid-state fiber laser operable to emit continuous-wave (CW) or quasi-continuous-wave (QCW).

According to a further aspect of the invention, the SWR system may be operable to maintain temperatures of at least a half of the continuous area of the CIT below an ablation point of the moving CIT concurrently to the ionization of other parts of the continuous area by the at least one light source.

According to a further aspect of the invention, an instantaneous interaction area may be static during at least the CLD with respect to outward optics of the SWR system, and the at least one light source is operable to ionize each part of the continuous area of the CIT when the respective part is positioned at the static instantaneous interaction area.

According to a further aspect of the invention, the SWR system may further include a movable solid target carrier operable to concurrently support at least the continuous area of the CIT, and a motor for moving the movable solid target carrier in order to move at least the continuous area with respect to the at least one light source. Optionally, the movable solid target carrier may be operable to rotate at angular velocity that exceeds 1,000 revolutions per minute (RPM). Optionally, the movable target carrier may be operable to propel the continuous area of the CIT to velocities that exceed 500 m/s during the CLD. Optionally, the SWR system may include at least one injector operable to propel ionizable target material onto the moving solid target carrier for forming the moving CIT. Optionally, the moving solid target carrier is operable to collect ionizable target material out of an ionizable target material reservoir, for forming the moving CIT.

According to a further aspect of the invention, the SWR system may further include optics for collecting the continuous SWR and for directing the continuous SWR toward a lithography object used in lithography manufacturing of computer chips.

According to another broad aspect of the invention, there is disclosed a method for generating SWR, the method comprising: (i) continuously illuminating for a CLD parts of a CIT that is moving with respect to a source of the illumination, wherein the CLD is longer than 500 nanoseconds; (ii) gradually ionizing during the CLD, as a result of the continuous illumination, a continuous area of the CIT in a continuous manner; and (iii) emitting continuous SWR, as a result of the gradual ionization, by ionized parts of the CIT of during the CLD; wherein the continuous area of the CIT is at least one order of magnitude larger than an illuminated area created by the continuous illumination projected on the CIT at any given moment during the CLD.

According to a further aspect of the invention, the continuous area of the CIT may be at least 100 times larger than an instantaneous interaction area.

According to a further aspect of the invention, the continuous illumination may be executed by at least one multi-Kilowatt class solid-state fiber laser operable to emit continuous-wave (CW) or quasi-continuous-wave (QCW) laser.

According to a further aspect of the invention, the method may include maintaining temperatures of at least a half of the continuous area of the CIT below an ablation point of the moving CIT concurrently to the ionization of other parts of the continuous area.

According to a further aspect of the invention, the method may include continuously moving different parts of the CIT into and out of a static instantaneous interaction area during the CLD, and ionizing each part of the continuous area when the respective part is positioned at the static instantaneous interaction area.

According to a further aspect of the invention, the method may include moving a movable solid target carrier that supports the continuous area of the CIT, thereby moving the continuous area with respect to a source of the illumination.

According to a further aspect of the invention, the moving may include rotating the movable solid target carrier at angular velocity that exceeds 1,000 revolutions per minute (RPM).

According to a further aspect of the invention, the moving may result in moving the continuous area of the CIT at velocities that exceed 500 m/s during the CLD.

According to a further aspect of the invention, the method may include propelling liquid ionizable target material onto the moving solid target carrier, thereby forming the moving CIT.

According to a further aspect of the invention, the method may include collecting by the moving solid target carrier ionizable target material out of an ionizable target material reservoir, thereby forming the moving CIT.

According to a further aspect of the invention, the method may include collecting continuous SWR and directing the continuous SWR toward a lithography object used in lithography manufacturing of computer chips.

According to a further aspect of the invention, the method may include cooling during the CLD at least a part of at least one cooled object selected from a group consisting of: ionizable target material of the CIT and a movable solid target carrier that supports the continuous area of the CIT.

### BRIEF DESCRIPTION OF THE DRAWINGS

In order to understand the invention and to see how it may be carried out in practice, embodiments will now be described, by way of non-limiting examples only, with reference to the accompanying drawings (each in accordance with examples of the presently disclosed subject matter), in which:

FIG. 1 is a schematical cross-section diagram illustrating an example of a short-wave radiation (SWR) system;

FIG. 2 is a schematical cross-section diagram illustrating an example of a SWR system used for lithography;

FIG. 3 illustrates a schematic diagram of a SWR system;

FIG. 4 illustrates examples of spatial distribution of parts of ionization target which are ionized in different times;

FIGS. 5A through 5D illustrate perpendicular views of schematic examples of a target carrier;

FIGS. 6A, 6B, and 7 illustrate schematic diagrams of SWR systems;

FIG. 8 is a flow chart illustrating a method for generating SWR;

FIGS. 9 and 10 illustrate schematic diagrams of SWR systems;

FIG. 11 is a flow chart illustrating an example of a method for generating SWR;

FIG. 12 is a schematic chart of optical conversion efficiency of SWR emission resulting from ionization of stationary ionizable material for different duration;

FIG. 12B is a schematic chart of conversion efficiency of SWR emission resulting from ionization of moving targets for different durations;

FIGS. 13A and 13B is a schematic illustration from different views, representing sizes of plasma clouds emitted from a stationary ionization target and from a moving ionization target when illuminated by different light pulses;

FIG. 14 is a schematic illustration representing sizes of plasma clouds emitted from a faster moving ionization target and a slower moving ionization target when illuminated by different light pulses;

FIG. 15 is a schematic illustration representing densities of steady state plasma clouds emitted from targets moving at different velocities;

FIGS. 16A and 16B offer a schematic comparison between a continuous illumination emitted toward a moving target in accordance with the teachings of the present invention to much shorter illumination periods; and

FIGS. 17A and 17B illustrate schematic diagrams of SWR systems.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF EMBODIMENTS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

In the drawings and descriptions set forth, identical reference numerals indicate those components that are common to different embodiments or configurations.

As used herein, the phrase “for example,” “such as”, “for instance” and variants thereof describe non-limiting embodiments of the presently disclosed subject matter. It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately or in any suitable sub-combination.

In embodiments of the presently disclosed subject matter one or more steps illustrated in the figures may be executed in a different order and/or one or more groups of steps may be executed simultaneously and vice versa. The figures illustrate a general schematic of the system architecture in accordance with an embodiment of the presently disclosed subject matter. Each module in the figures can be made up of any combination of software, hardware and/or firmware that performs the functions as defined and explained herein. The modules in the figures may be centralized in one location or dispersed over more than one location.

Any reference in the specification to a method should be applied mutatis mutandis to a system capable of executing the method and should be applied mutatis mutandis to a non-transitory computer readable medium that stores instructions that once executed by a computer result in the execution of the method. Any reference in the specification to a system should be applied mutatis mutandis to a method that may be executed by the system and should be applied mutatis mutandis to a non-transitory computer readable medium that stores instructions that may be executed by the system.

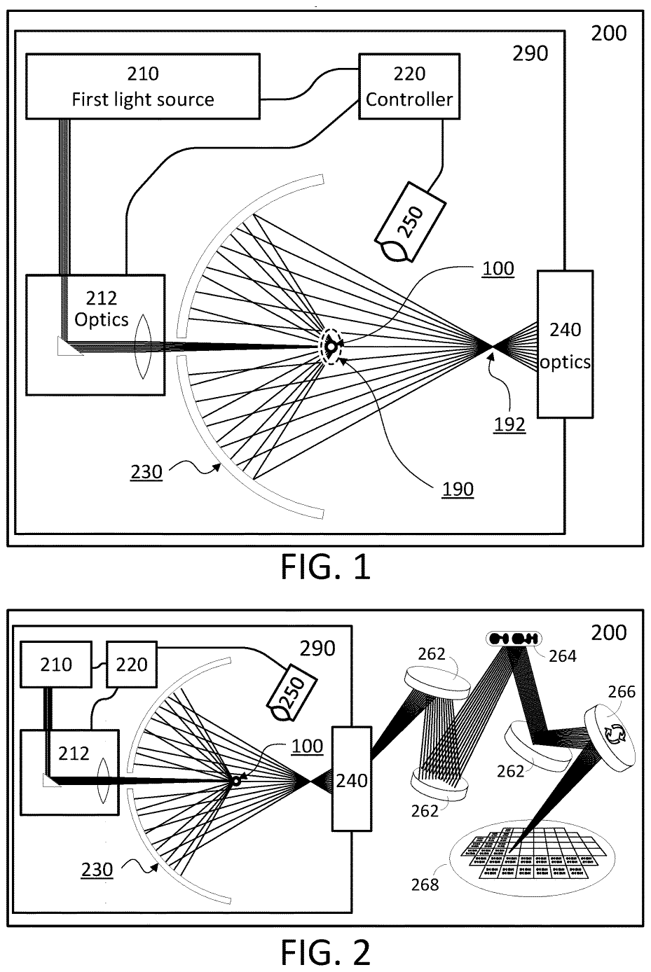

FIG. 1 is a schematical cross-section diagram illustrating an example of system 200, in accordance with examples of the presently disclosed subject matter. System 200 is operable to generate Short Wave Radiation-SWR (e.g., EUV light) and may optionally also include additional components which are not part of the light emission subsystem. For example, such components may utilize SWR generated by system 200 (e.g., EUV light) for different uses in chip manufacturing (e.g., lithography, inspection), or any other field, such as imaging, shadowgraphy, etc. The generated SWR may have a characteristic wavelength of 13.5 nm, but other SWR wavelengths may also be emitted and optionally utilized. For example, 6.7 nm or shorter. Within the context of this disclosure, the terms short-wave radiation (SWR) pertains to all electromagnetic radiation having wavelength that is shorter than 200 nm, and especially to radiation between 0.4-200 nm. Short-wave radiation includes different parts of the electromagnetic spectrum, such as EUV and X-ray. The emitted SWR radiation (by system 200 or by any of the systems and methods disclosed herein) may have its power peak at different wavelength, for example in order to suit the intended use of the SWR. For example, the SWR generated using the systems and methods discussed below may have a peak power at a wavelength of 1.7 nm, 4.2 nm, 6.7 nm, 13.5 nm, 50 nm, 100 nm, etc. The actual emitted SWR spectrum may be broad with respect to the desired wavelength range (e.g., 13.5 nm±1%), and the undesired emitted SWR may be filtered out, emitted anyway, lost in the system (e.g., due to optics being tailored to specific wavelengths), or handled in any other suitable fashion. By way of example, some lithography uses may require 13.5 nm±1%, while other applications may require broader spectrum.

System 200 includes first light source 210 which provides energy to system 200 and which is used to illuminate one or more objects (referred to “targets” 100), thereby at least partly ionizing such targets 100 (and exciting the atoms of such ionized parts of the targets 100) for emitting SWR (e.g., EUV light). Different types of light sources may be used, such as lasers (e.g., Gas lasers, CO₂ laser, diode laser, fiber laser, Q-switched laser, diode pumped lasers and diode pumped solid state (DPSS) lasers), pulsed light source, continuous light source (e.g., continuous wave, CW, laser), etc. Various optical components (collectively denoted “optics 212”) direct light of first light source 210 onto targets 100 within system 200. Optics 212 may include mirrors, curved mirrors, parabolic and spherical mirrors, prisms, lenses, and any other types of equipment which may be used for transforming light propagation. Optics 212 may optionally include controllable components for changing properties of light such as propagation direction, focusing properties, optical wavefront of the light beam directed toward the targets 100 (e.g., in order to accommodate for fluctuations in the positioning of different targets 100), but this is not necessarily so. Some examples for optics 212 (and any other SWR optics discussed below) include: motorized optics, deformable mirrors, piezoelectric actuators, optical modulators, optical isolators. system 200 may optionally include controller 220 for controlling different components of system 200. For example, controller 220 may include a computer, one or more computer processor, and any other components which may be required for its operation (e.g., memory units, cables, sensors, power supply). Optionally, one or more sensors 250 may provide to controller 220 information indicative of kinematic parameters of one or more of the targets 100, such as location within system 200 (and especially with its SWR emission module 290), orientation, shape, size, velocity, acceleration, spin, etc. Optionally, one or more sensors 250 may provide to controller 220 information indicative of other parameters of one or more targets (e.g., temperature, color, structure, position, velocity), of other components of the system (e.g., laser orientation, temperature), and so on. Controller 220 may use such parameters to control the operation of first light source 210, of optics 212, or of any other component of light source 220. Examples of types of sensors 250 which may be implemented include cameras, radar, diodes, power meters, and wavefront sensors. While only one first light source 210 is exemplified in FIG. 1, it is noted that multiple first light sources 210 may optionally be implemented, directed to hit targets 100 from one or more directions and in one or more locations 190 within SWR emission module 290. Optionally, a light of a single first light source 210 (out of the one or more included in system 200) may be split into several light beams which are projected onto a single target 100 from different directions (concurrently, partly concurrently, or otherwise). It is further noted that several light sources can be combined into one (e.g., into a single coherent light beam).

SWR (e.g., EUV light) resulting from the ionization of at least a part of target 100 is emitted in different directions (e.g., in a Lambertian or an isotropic emission), and is then collected and/or directed toward outward optics 240, which may be used to directing SWR out of system 200 (e.g., to another system), or from SWR emission module 290 to other parts of system 200 (e.g., optional SWR lithography components of system 200 as exemplified in FIG. 2). The optical components used for collecting and/or directing emitted light toward outward optics 240 (also referred to as “collection optics 240”) are collectively denoted 230, and are represented in FIG. 1 by a concave mirror (e.g., suitable for EUV wavelengths). It is nevertheless noted that other types of mirrors, as well as other types of optical components may be used for directing SWR toward optics 240. While not necessarily so, one or more of the optional mirrors of optics 230 may be a multilayered mirror (MLM). MLMs are mirrors which may be made from a substrate material (e.g., quartz, silicon, glass), shaped in different shapes (e.g., plane, concave, convex, paraboloid, ellipsoidal etc.) which is coated in multiple layers of different coating (e.g., selected from the group consisting of Ru/Si, SiC/Mg, Mo/Si, Zr/Al, Cr/C, etc.), which assist in reflecting SWR (e.g., EUV light). In some examples, the emitted Short-Wave Radiation (SWR) emitted from target 100 is collected by the MLM (or other type of optics 230) and reflected backwards towards a designated beam direction, e.g., toward optics 240. While not necessarily so, the directed SWR may pass through a point named intermediate focus 192, but system 200 doesn't have to necessarily include such an intermediate focus.

The wavelength of the SWR emitted by system 200 is determined by the material of which an ionized target 100 is made of and the intensity of first light source 210. Additional factors determining the wavelengths of the emitted SWR include wavelength of hitting radiation, geometrical properties of the interaction, temperature, and plasma density. For example, target 100 which are made of Tin (Sn) emit EUV light having a spectral peak at about 13.5 nm. However, other materials for targets 100 (also referred to as “emitters”) can be used as well, among them, various high Z materials such as rare earth metals or higher Z metals such as gold or lead, as well as structures and materials that combine several elements, such as layered or mixed materials.

Referring to the one or more locations 190, it is noted that there are many advantages to a smaller location 190 in which system 200 expects each target 100 to be located when being ionized by the laser. For example, optics 212 can be simpler, cheaper, and more precise. Moreover, if multiple targets 100 are being ionized in the same relatively small location 190, the overall brightness of SWR emission module 290 increases, as it is possible to focus the emitted SWR to a more concise beam when delivered to optics 240.

FIG. 2 is a schematical cross-section diagram illustrating an example of system 200 used for lithography, in accordance with examples of the presently disclosed subject matter. In the example of FIG. 2, SWR (e.g., EUV light) generated by ionization of one or more targets 100 is directed by outward optics 240 toward lithography mask 264 via various optical components (such as but not limited to mirrors 262). From lithography mask 264, patterned short-wave light (patterned and/or modulated by mask 264) is deflected via various optical components (such as but not limited to mirrors 262, steerable mirrors 266) toward wafer 268 (e.g., a silicon wafer, a germanium wafer, silicon oxide wafer) where it is used to pattern parts of the wafer using lithography. It is noted that other types of optical components may be used for directing and managing light in its path from outward optics 240 to an aiming point of system 200 (e.g., on the wafer), such as but not limited to: mirrors, multi-layer mirrors (MLM), grazing incidence reflectors, Curved MLM, spherical or parabolic MLM, reflection masks, masks, beam blockers, pellicles, lenses, prisms, waveguides, and so on, all of which could be controllable (e.g., steerable) or not. A few other examples of uses for short-wave radiation (e.g., EUV light) of system 200 which are not illustrated in FIG. 2 include wafer inspection during wafer manufacturing, mask inspection for lithography masks used in lithography (whether of wafers or other), MLM inspection and light source used for research, and so on.

Referring to first light source 210 (e.g., laser), it is noted that the same light source may be put to other uses other than the actual ionization and excitation of targets 100. For example, first light source 210 may emit weaker pulses prior to the main, ionizing pulses for modifying a shape of the hit target 100 (e.g., from a sphere-like shape to a disk-like shape). Such weaker pulses are also referred to as “pre-pulses”. Alternatively, such pre-pulses may be emitted by one or more light sources that are not used for the target excitation that leads to the emission of SWR as discussed above. Optionally, an energy level of the pre-pulse may be significantly lower (e.g., <10%) than the ionizing main pulse, and may optionally have the same wavelength or a hormonic of the wavelength of the main (ionizing) pulse. A nonlimiting example may include a main pulse of an Nd: YAG laser having energy of 100 mJ at 1064 nm wavelength, while the pre-pulse is emitted by the same laser, has energy of less than 10 mJ and wavelength of either 1064, 532 or 266 nm. Optionally, the pre-pulse may also be emitted by a different laser system with a different wavelength from the main pulse. Optionally, the pre-pulse may have different time duration than the main pulse (e.g., much shorter, such as by a scale of ×10, ×100 ×1,000 and so on) and/or different spatial properties (e.g., different focal spot or position). For example, the main pulse can be emitted by a CO₂ laser or Nd:YAG and the pre-pulse may be emitted by a TI:Sa laser, Ytterbium laser, solid-state laser, and so on. It is noted that such pre-pulses may also ionize parts of the target, but to a lesser extent due to their much lower intensity

Optionally, system 200 may include one or more magnets, coils, or other ways of forming a magnetic field (not illustrated) for diverting unwanted ions or other charged particles resulting from ionization of target 100, and/or for directing ionized particles in desired direction (e.g., may also be used to confine the plasma). Optionally, system 200 may include one or more injector for injecting gas into at least a portion of system 200 for reducing unwanted effects of such debris or for any other reason. Optionally, system 200 may include at least one pellicle having good transmission of SWR for reducing unwanted effects of such debris. It is noted that system 200 may include any one or more of the different mechanisms discussed in this paragraph, alternative mechanisms for the same end, or none.

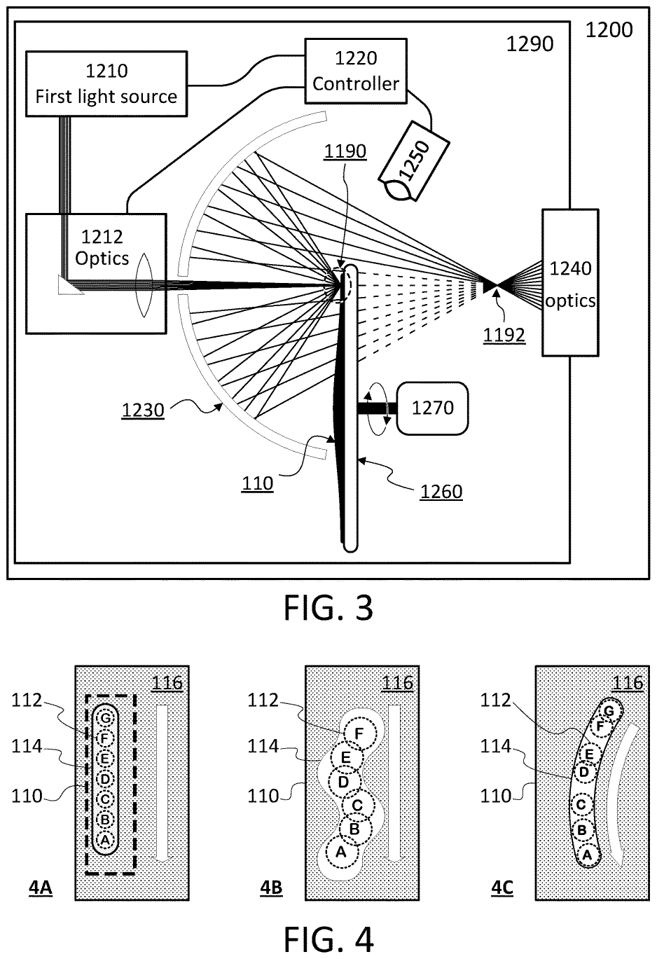

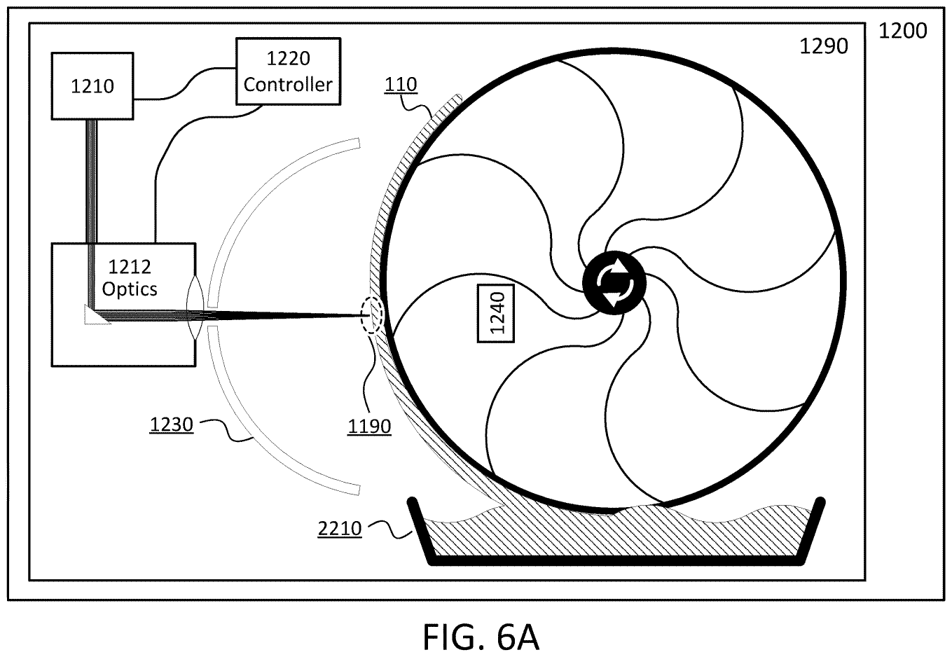

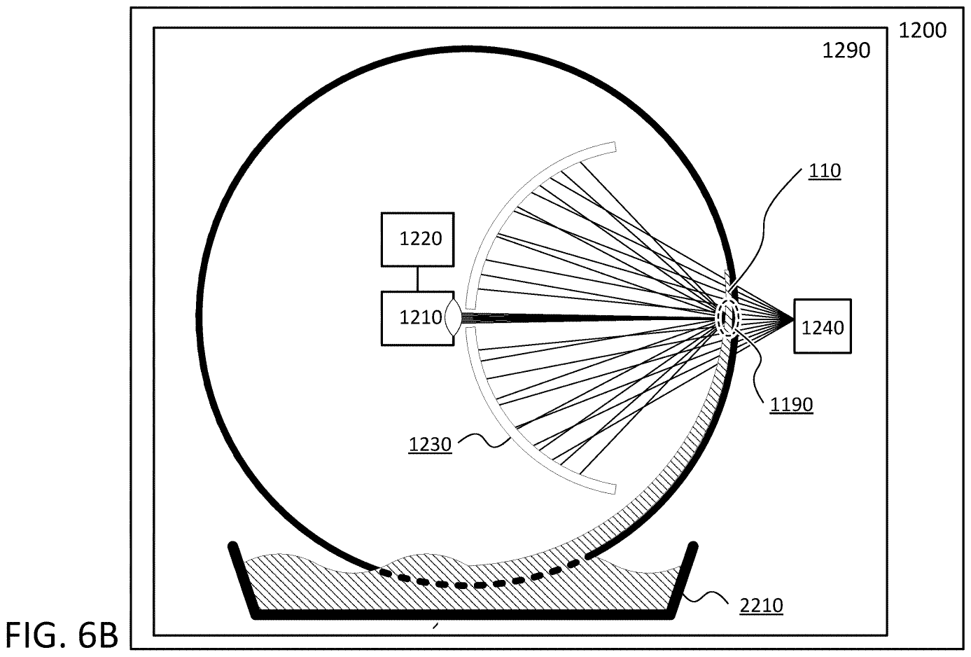

FIGS. 3, 6A, and 6B illustrate schematic diagrams of short-wave radiation systems 1200 in accordance with examples of the disclosed subject matter. Short-wave radiation system 1200 (also referred to as “short-wave system 1200”, “EUV system 1200” and “system 1200”) is designed for generating short-wave radiation, and includes at least optics 1230 (representing by an optional MLM mirror) and at least one light source 1210. It is noted that optionally, system 1200 may be a variation of system 200, with a specific characteristic that the ionization targets of system 1200 are not individual mass limited targets but rather larger continuous targets 110 whose parts are ionized sequentially over longer exposures to the ionizing illumination (of the at least one light source). Longer pulses of different durations may be implemented, as discussed below in greater detail. For example, the duration of each such longer pulse may be substantially longer than the time it takes a plasma spatial profile, and hence the SWR emission, to reach a steady state. As discussed below in greater detail, the spatial profile of the plasma (and correspondingly the SWR emission), may be regulated by fast motion of the ionization target with respect to the light source. Any component, group of components, or interaction between components that was discussed with respect to system 200 may be incorporated, mutatis mutandis, to system 1200. Components of system 1200 whose reference signs (also known as “reference numbers” or “reference numerals”) begin with the digit “1” and which have a counterpart in system 200 without the leading digit “1” (e.g., light source 1210 and light source 210, SWR emission module 1290 and SWR emission module 290, controller 1220 and controller 220) may be a variation of that corresponding component of system 200 even if not explicitly stated, and any discussion above pertaining to such a component of system 200 is also applicable (optionally as a variation or alternative) to the corresponding component of system 1200, mutatis

System 1200 includes one or more light sources 1210 which are collectively operable to emit light toward a continuous ionization target (CIT) that is moving with respect to the at least one light source 1210. The one or more light source 1210 may be, for example, of any of the types discussed with respect to light source 210, such as CW laser, quasi-CW laser, pulsed laser, and so on. Any repetition rate can be used (where in CW illumination there isn't necessarily a repeated cycle of illumination). It is noted that illumination by light source 1210 (as well as light sources 210 and 1210′) may be used for ionizing ionizable target material as well as for further heating or otherwise exciting the ionizable target material, e.g., in order to reach the needed level of excitation of the ionized target material (i.e., plasma). The excited target material emits SWR and the spectrum of the SWR depends (among other properties) on the excitation of the plasma. It is noted that the number of electrons which needs to be removed from an atom of the ionized target material during the ionization by the respective light source may vary depending on the used material, the required SWR wavelength, and so on. For example, in order to excite Sn target for effective emission of SWR at wavelength of 13.5 nm (EUV), the Sn atoms need to be heated and excited so that the atoms are ionized at least 8 times).

Referring to system 1200 as a whole (as well as to the systems and the methods discussed below), it is noted that as the CIT moves with respect to the illumination, each point of the continuous area (i.e., the area that is being gradually ionized during the CLD in a continuous manner) is being illuminated for a duration of time which is significantly shorter than the CLD. For example, referring to the example of FIG. 4A (discussed below in greater detail), each point on the area denoted “A” can only be illuminated when the illumination of the light source is directed, at least partly, to area “A”. As CIT 110 moves during the CLD and area “A” is no longer illuminated, all points on “A” cool down, while points on other areas of continuous area 114 (e.g., areas “B”, “C”, etc.) are being gradually ionized, while the interaction of points in area “A” has concluded.

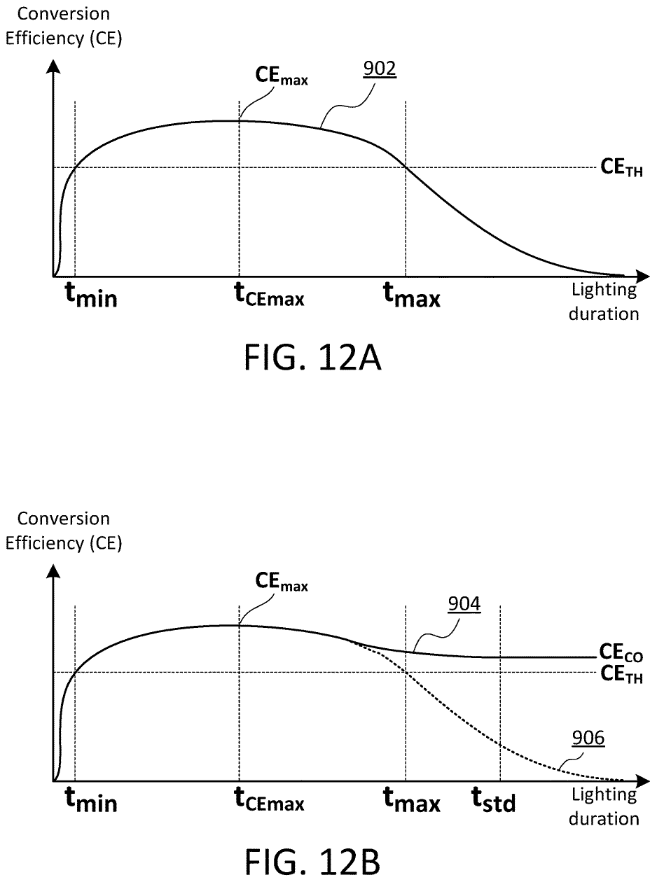

Optionally, system 1200 may be operable to ionize and/or move CIT 110 during the CLD such that no point of CIT 110 is being illuminated for longer than 100 ns (or even 50 ns, 30 ns, or 10 ns, in some of the possible embodiments). Optionally, system 1200 may be operable to ionize and/or move CIT 110 during the CLD such that no point of CIT 110 is being illuminated for longer than 100 ns (or even 50 ns, 30 ns, or 10 ns, in some of the possible embodiments) while the CLD exceeds 500 ns (or even 1 ms, 5 ms, 100 ms, CW etc.). Optionally, system 1200 may be operable to ionize and/or move CIT 110 during the CLD such that no point of the continuous area 114 is being illuminated for longer than 100 ns (or even 50 ns, 30 ns, or 10 ns, in some of the possible embodiments). Optionally, system 1200 may be operable to ionize and/or move CIT 110 during the CLD such that no point of continuous area 114 is being illuminated for longer than 100 ns (or even 50 ns, 30 ns, or 10 ns, in some of the possible embodiments) while the CLD exceeds 500 ns (or even 1 ms, 5 ms, 100 ms, CW, etc.). Optionally, system 1200 may be operable to ionize and/or move CIT 110 during the CLD such that no point of CIT 110 is being illuminated for longer than ×0.2 of the CLD (or even ×0.1, ×0.01, or ×0.001 of the CLD, in some of the possible embodiments). Optionally, system 1200 may be operable to ionize and/or move CIT 110 during the CLD such that no point of CIT 110 is being illuminated for longer than ×0.2 of the CLD (or even ×0.1, ×0.01, or ×0.001 of the CLD, in some of the possible embodiments) while the CLD exceeds 500 ns (or even 1 ms, 5 ms, 100 ms, CW etc.). Optionally, system 1200 may be operable to ionize and/or move CIT 110 during the CLD such that no point of the continuous area 114 is being illuminated for longer than ×0.2 of the CLD (or even ×0.1, ×0.01, or ×0.001 of the CLD, in some of the possible embodiments). Optionally, system 1200 may be operable to ionize and/or move CIT 110 during the CLD such that no point of continuous area 114 is being illuminated for longer than ×0.2 of the CLD (or even ×0.1, ×0.01, or ×0.001 of the CLD, in some of the possible embodiments) while the CLD exceeds 500 ns (or even Ims, 5 ms, 100 ms, CW, etc.). It is noted that the time each individual point is being illuminated depends on the velocity of CIT 110 at the vicinity of the illuminated area and on the dimensions of the instantaneously illuminated area (at least in the direction of movement of the CIT), regardless of the duration of the entire CLD. Referring to the example set forth below with respect to FIGS. 12A and 12B, it is noted that optionally, system 1200 may be operable to ionize and/or move CIT 110 during the CLD such that no point of CIT 110 is being illuminated for longer than tₘₐₓ, as defined with respect to FIGS. 12A and 12B.

It is noted that whenever the description of systems or methods discussed an optional condition pertaining to the relative sizes of the continuous area of CIT and an illuminated area projected by the at least one light source on the CIT (e.g., requiring that the former being at least one order of magnitude than the latter), any one of the conditions pertaining to durations discussed in the previous paragraph may be used-instead of or in addition to-to the aforementioned optional condition pertaining to the areas.

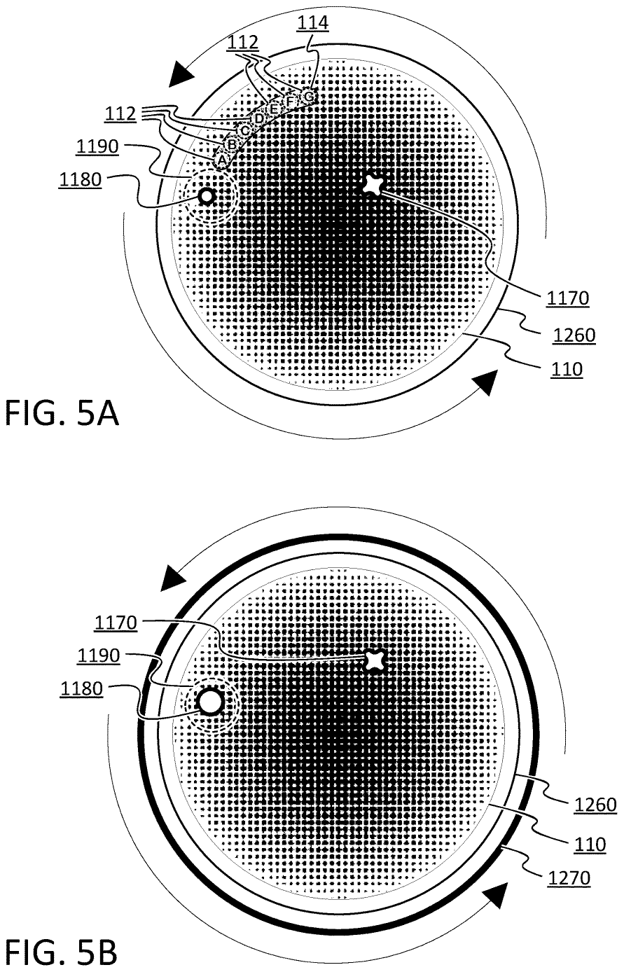

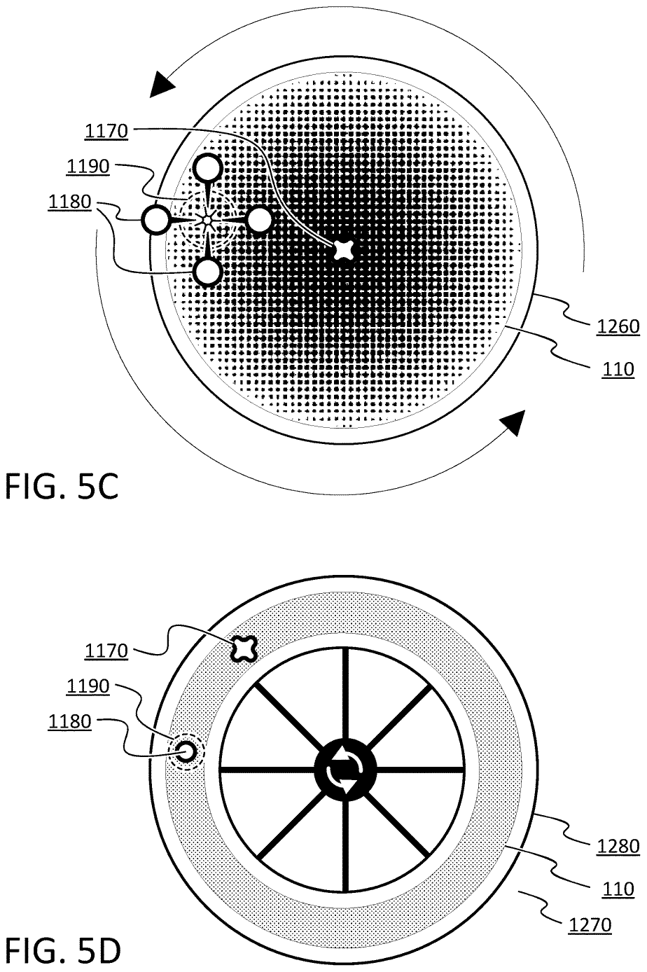

FIG. 4 includes three diagrams, each illustrating an example of spatial distribution of parts 112 of ionization target 110 which are ionized in different times, in accordance with examples of the presently disclosed subject matter. In each of the diagrams 4A, 4B, and 4C the direction of movement of CIT 110 is illustrated by a white arrow. It can be seen that the different parts 112 which are ionized at different times (as discussed below) may partly overlap one another or not. It is also seen that the term “Continuous ionization target” may pertain to the entire continuous moving ionization matter 116 (as demonstrated for example in diagrams 4B and 4C) or only to part of the continuous moving ionization matter 116 (as demonstrated for example in diagrams 4B and 4C). The types of motions illustrated are linear (4A), sinusoidal (4B), and circular (4C), but these are just example, and any suitable type of motion may be implemented, whether confined to a single plane as in those examples, or in a 3D space (e.g., as exemplified in FIGS. 6A and 6B). One nonlimiting example of how this motion of different parts can be integrated into system 1200 is provided with respect to FIG. 5A.

The at least one light source 1210 emits light toward different parts 112 of moving CIT 110 while it is moving (e.g., as exemplified in the diagrams of FIG. 4), Illuminating and ionizing only part of target 110 at each moment, while leaving most of target 110 below its point of ablation (at a solid state and/or at a liquid state). Especially, while ionizing parts of target 110, the at least one light source is operable to:
a. Illuminate a first part (e.g., 112A) of the moving CIT, thereby ionizing the first part of the moving ionization target to emit first short-wave radiation, while a temperature of a second part (e.g., 112F) of the moving CIT is concurrently maintained below the ablation point of the moving ionization target; and
b. After the ionization of the first part, illuminating the second part of the moving CIT, thereby ionizing the second part of the moving CIT to emit second short-wave radiation.

Optics 1230 are designed and positioned so that optics 1230 directs the first short-wave radiation and the second short-wave radiation toward a designated beam direction (e.g., toward an intermediate focus 1192 of EUV radiation system 1200 if implemented, or toward optics 1240). While not necessarily so, optics 1230 may be operable to direct short-wave radiation generated by the ionization of other parts of target 110 by the one or more light sources 1210 at other times. It is noted that the ionization of the first part (e.g., 112A) may emit additional SWR on top of the first SWR, and that the term “first SWR” pertains only to part of the SWR emitted by ionization of the first part which is collected and directed by optics 1230 toward a designated beam direction (e.g., toward intermediate focus 1192, if any, or toward 1240). It is noted that the designated beam direction may or may not be constant in time. It is noted that the designated beam direction may optionally be directed toward a specific point in system 1200, such as an optical channel towards another system or module (such as a lithography module, for example).

FIGS. 3, 5, 6, 7, and 8 illustrate various examples of system 1200, in which target 110 (made of any suitable target Ionizable target material, e.g., including at least one of tin, gadolinium, gold) is moved with respect to at least one light source 1210 by a moving target carrier 1260 made from a solid material (e.g., tungsten, ceramic, stainless steel, copper). That moving target carrier 1260 moves at least a part of target 110 (and optionally all of it) by means of friction between target 110 and target carrier 1260 (or by other means, such as electromagnetic attraction). The moving of target 110 may be done using different ways (e.g., rotating using a wheel or a disk, moving by a conveyer belt or similar mechanism) and in different ways of motion (e.g., rotation, linear motion, harmonic motion, sinusoidal motion), as long as different parts of target 110 are illuminated in different times during a single continuous illumination (e.g., CW, QCW, elongated pulse) by the at least one light source 1210. While different aspects are discussed with respect to examples which show different forms of movement, it is noted that such aspects may be implemented for any suitable type of motion, using any suitable type of target carrier 1260. Target carrier 1260 may be made of any one or more suitable materials, such as tungsten, ceramic, stainless steel, copper, and so on. Some examples of characteristics for some of the materials which are suitable for a target carrier include: material that has optimal thermo-mechanical properties such as mechanical strength and rigidity, thermal properties such as resistance to high temperatures (high melting temperature point), thermal conductivity properties, material that is suitable for operation in vacuum in particular at high temperatures and properties suitable for carrying the CIT material on it, such as optimal “coupling” and structural roughness properties.

FIG. 3 illustrates an example of system 1200 in which target 110 (e.g., tin target) is rotated about an axis which is parallel to a symmetry axis of the at least one light source 1210 by a rotating target carrier 1260 (e.g., a rotating disk, a rotating wheel, a rotating curved cap) (e.g., a spherical cap, a spheroidal dome) made from a solid material (e.g., tungsten, ceramic, stainless steel, copper) which rotates at least a part of target 110 (and optionally all of it) by means of friction between target 110 and target carrier 1260 (or by other means, such as electromagnetic attraction). A surface of target carrier 1260 which is in contact with target 110 may be of one or more different textures, e.g., smooth or corrugated. Further details are discussed below. FIGS. 5A through 5D illustrate perpendicular views (to the view of FIG. 3) of schematic examples of target carrier 1260. As illustrated in FIG. 5A, the at least one light source 1210 illuminates an area 1180 on moving target 110 (e.g., having a diameter that will yield an optimized intensity for production of SWR (e.g., EUV), e.g., 5-10 μm, 10-20 μm, 20 μm-40 μm, 40 μm-60 μm, 60 μm-100 μm. Optionally, the intensity of light that the at least one light source 1210 cast on area 1180 on moving target 110 is between 1010-1011 W/cm². Optionally, area 1180 is not moving with moving target 110, but is rather substantially immobile with respect to any one or more of: at least one light source 1210, optics 1230, and optics 1240. However, optionally system 1200 may be able to controllably change the location of area 1180 with respect to the at least one light source 1210 (e.g., within a somewhat larger area 1190 which is the area from which SWR may be collected by optics 1230 and directed toward a designated beam direction (e.g., toward intermediate focus 1192 or optics 1240). Optionally, system 1200 may controllably move area 1180 within area 1190 based on information collected by one or more sensors 1250, and/or on any information (e.g., a predetermined scanning scheme).

Referring to FIGS. 4 and 5A, area 114 illustrates part of moving target 110 which is about to be covered by area 1180 when target 110 rotates counterclockwise, as exemplified in the diagram. Two or more areas 112 of the larger area 114 (and potentially other parts of area 114, such as the unmarked areas between the different areas 112) will be ionized by illumination of the at least one light source 1210 (e.g., in the next revolution of target carrier 1260). It is noted that each area 112 may be ionized somewhat gradually (e.g., due to movement with respect to a substantially fixed continuous or quasi continuous illumination). The discrete distinguishing in the description between different parts 112 of CIT 110 is useful for the explanation, but the actual dynamics of ionization may be a gradual continuous ionization along a continuous area 114, whether at a constant speed or a varying speed.

The velocity of the ionizable target material of the CIT at the time of ionization (e.g., when within the instantaneous interaction area) may be determined in different ways in order to suit the specific system implemented. For example, that velocity may be determined to qualify with any specific combination of one, two, or all of the following optional criteria:
a. Given a transient time from the beginning of light source 1210 illumination until the SWR emission reaches a steady state (e.g., TSTD in FIG. 12B), the displacement of the target within that transient time should be larger than the illumination spot size and/or than the size of the instantaneous ionization area.
b. The velocity should render a plasma profile of a plasma cloud emitted from the CIT non symmetric, such that a dimension of the plasma cloud along the direction of motion of the CIT at that area is at least twice as large as a dimension of the plasma cloud at a perpendicular direction.
c. The velocity is sufficient to improve conversion efficiency from laser power to SWR power by a factor of at least 2 as a result of the motion itself.

Optionally, system 1200 may implement continuous, quasi-continuous or otherwise relatively lengthy scheme of lighting, resulting in a continuous SWR emission (or a semi-continues, or a correspondingly lengthy SWR emission). In such case, the at least one light source 1210 may be operable to continuously emit light toward the moving CIT, sequentially ionizing parts of the moving CIT in a continuous manner between at least the first part and the second part, for emitting by ionized parts of the CIT a continuous SWR that includes the first SWR and the second SWR. After ionizing the second part, the at least one light source 1210 may continue emitting radiation for ionizing additional parts of target 110, or may stop emitting before resuming emission after a stop (brief or lengthy one). It is noted that a moving continuous target which is much larger than area 1180 (e.g., more than ×1,000, ×100K, ×10M, etc. times larger) may also be implemented in system 1200 with pulsed light, in which the at least one light source 1210 pauses light emission between the ionization of the first part 114 and the second part 114.

Optionally, system 1200 may include a static ionization location (e.g., area 1190 or a volume 1190) positioned along at least one illumination cone of the at least one light source 1210 (and potentially along all of the at least one illumination cones), and the at least one light source 1210 is operable to ionize the first part (e.g., 112B) while positioned at the static ionization location 1190 and to ionize the second part (e.g., 112C) at a later time, while the second part is positioned at the static ionization location 1190. The area of the static ionization location (or a cross-section of the station ionization volume which is perpendicular to a symmetry axis of the light sources 1210 assembly) is smaller than a surface area of the CIT 110. The relative sizes between the two may vary, depending on the specific implementation of system 1200 (e.g., by a factor of at least ×5, ×10, ×102, ×103, ×105, ×108, ×1010, etc.). The static ionization location may be static with respect to a light source 1210, to outward optics 1240 (which may be positioned along the designated beam direction), or both.

Likewise, the moving target may be larger (potentially-much larger) than an instantaneous illumination spot of the at least one light source 1210 on moving continuous target 110 (e.g., area 1190). The relative sizes between the two may vary, depending on the specific implementation of system 1200 (e.g., by a factor of at least ×5, ×10, ×102, ×103, ×105, ×108, ×1010, etc.). Optionally, the at least one light source 1210 can concurrently ionize an instantaneous maximal area of the CIT that is smaller than a surface area of the CIT 110. The relative sizes between the two may vary, depending on the specific implementation of system 1200 (e.g., by a factor of at least ×5, ×10, ×100, ×1,000, ×1,000K, ×100M, etc.).

The instantaneously ionized area of target 110 (or area 1180) may be much smaller than a surface area of parts of the CIT 110 which are ionized by a continuous light of the light source which ionizes the first part and the second part. The relative sizes between the two may vary, depending on the specific implementation of system 1200 (e.g., by a factor of at ×5, ×10, ×102, ×103, ×105, ×108, ×1010, etc.). It is noted that while a strictly continuous target may be used, it is also possible to use a target which is substantially continuous. Such a substantially continuous target may include thin breaks, splits, spaces, etc., e.g., whose width is less than 20% of the width of an instantaneous interaction area (in which light of the light source interacts with the CIT to generate plasma), such that even when such a possible space or a break (in some implementations) in the CIT is being illuminated by the at least one light source 1210, there is sufficient ionizable target material being concurrently illuminated and ionized to maintain an uninterrupted SWR emission. Optionally, system 1200 may be used solely with strictly continuous ionization targets.

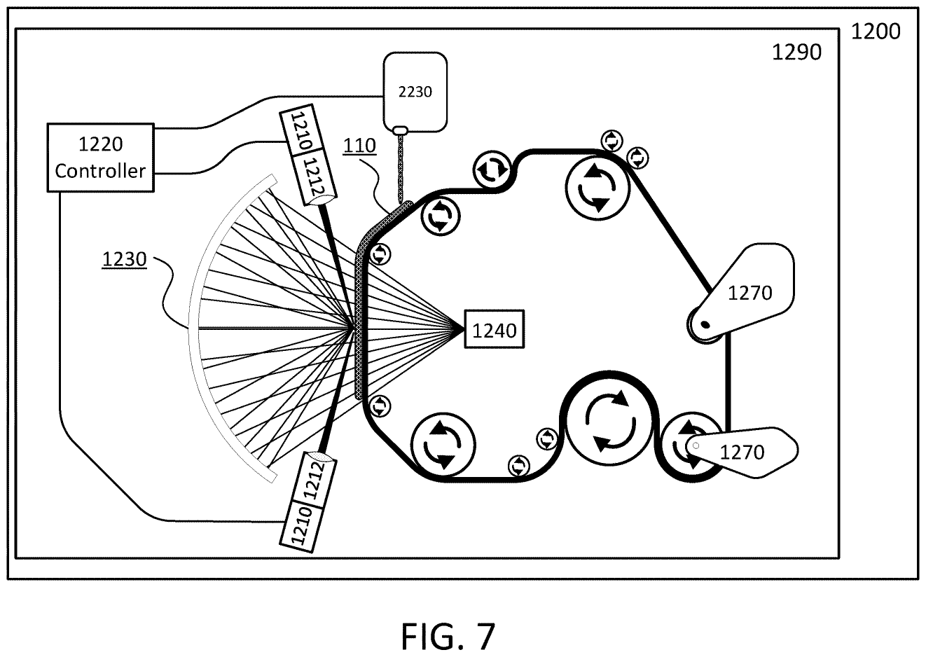

As aforementioned, continuous moving target 110 may be supported and/or propelled by a movable solid target carrier 1260 made from a material which is less affected by light source 1210 illumination and which may optionally have optimized properties in terms of material and surface geometry to support the target (e.g., tungsten, ceramic). Such a target carrier 1260 may be rigid or flexible, and may be implemented in different ways, such as rotating (e.g., such as the examples of FIGS. 5A through 5D), moving in a closed loop (e.g., the conveyer belt mechanism of FIG. 7), and moving linearly in an open loop.

Optionally, movable solid target carrier 1260 may be operable to concurrently support (partly or fully) at least the first part and the second part of the moving CIT (which, as aforementioned, are ionized at different time by a temporally continuous illumination). System 1200 may further include one or more motors (e.g., motor 1270) which is capable of moving the movable solid target carrier 1260 in order to concurrently move at least the first part of the CIT 110 and the second part of the CIT 110 with respect to the at least one light source 1210.

Referring to movable target carriers 1260, it is noted that relatively fast velocities (e.g., exceeding 1 Km/s) may be implemented, e.g., in order to achieve sufficient SWR power at an output of system 1200. If the required velocity is achieved by rotation, than depending on the radius of rotation, such linear velocity may be achieved by rotating movable target carriers 1260 at a suitable angular velocity exceeding 1,000 RPM, exceeding 5,000 RPM, exceeding 10,000 RPM, exceeding 20,000 RPM, exceeding 100,000 RPM, exceeding 200,000 RPM, and so on (RPM standing for revolutions per minute).

Referring to any type of motion of moving continuous target 110 (e.g., circular, linear, sinusoidal), it is noted that relatively fast linear velocities may be implemented for the ionized areas 112 during ionization, e.g., in order to achieve sufficient SWR power at an output of system 1200. For example, movable target carrier 1260 may be operable to propel the first part of the CIT 110 and of the second part of the CIT 110 to velocities that exceed 100 m/s when ionized by the at least one light source. For example, velocities ranges of 100-500 m/s, 300-1,000 m/s, or 1,000-2,000 m/s may be implemented.

Ionizable target material (e.g., tin, gadolinium, gold) may be applied to the moving target carrier 1260 in various ways, such as (but not limited to) injection onto, pouring onto, deposition onto, and collecting by target carrier 1260 itself. It is noted that while not necessarily so, the ionizable target matter may be applied to target carrier 1260 when at least a portion of target carrier which supports at least a part of moving target 110 is moving at operation speed, and optionally concurrently with ionization of one or more areas 112 of target 110. By way of example, system 1200 may optionally include at least one injector 2230 operable to propel ionizable target material onto the moving solid target carrier for forming the moving CIT 110 (e.g., as exemplified in FIG. 7). By way of example, moving solid target carrier 1260 may optionally be operable to collect ionizable target material out of an ionizable target material reservoir 2210, for forming the moving CIT 110 (e.g., as exemplified in FIGS. 5 and 6).

As discussed above in greater detail, system 1200 (like system 200) may optionally include optics for collecting emitted SWR (and especially the first SWR and the second SWR, in the case of system 1200) and for directing that SWR (e.g., first SWR and second SWR) toward a lithography object (e.g., a lithography mask, an inspected lithography wafer) used in lithography manufacturing of computer chips. It is noted that a lithography object may also be inspected by such SWR. Naturally, the short-wave radiation generated by system 1200 may be put to any other use, and is not limited to lithography.

Optionally, system 1200 may include collector 1280 for collecting excesses of ionizable target material (e.g., tin) which is splashed off (or otherwise dislodged, discharged, or unloaded off) of target carrier 1260. An illustrative example of such a collector 1270 is provided in FIG. 5B. While FIG. 5B Illustrates a collector 1280 only with respect to a rotating disk/cap target carrier 1260, it is noted that collectors may be implemented for each of the possible implementations. For example, collector 1280 may collect residual ionizable target material that has disconnected from the target carrier due to the high target carrier velocity. Once collected by collector 1280, such residual target material may be directed back into ionizable target material reservoir (e.g., reservoir 2210), or directly back to CIT 110 (e.g., via injector 2230). Optionally, collector 1280 may store the residual ionizable target material within the collector 1280 and be replaced once it has collected a substantial amount of residual ionizable target material.

Optionally, the at least one light source 1210 may include a plurality of light sources 1210 (e.g., a plurality of lasers) which are symmetrically arranged around an illumination symmetry axis (e.g., crossing area 1180). An illustrative example of such a configuration is provided in FIG. 5C. Such symmetrically arranged light sources may operate substantially in unison. Utilization of multiple light sources may be implemented for different reasons, such as (but not limited to) utilizing higher energy and/or higher intensity levels (compared to what is possible with a single unit) or high average power levels, and clearing way for SWR generated by system 1200. Such a symmetrical arrangement of light sources 1210, each of which are positioned off the symmetry axis, may be accompanied by a MLM mirror (part of optics 1230), which do not have a hole along the symmetry axis, where a significant part of the generated SWR hits the MLM mirror. An example of such an arrangement (illustrating two out of possibly larger amount of symmetrically arranged light sources 1210) is offered in FIG. 7. The plurality of light sources may include 2, 3, 4, 5, 6, 7, 8, or any other number of light sources, which may be substantially interchangeable units (e.g., the same type of laser), but not necessarily so.

System 1200 may include various optical components (collectively denoted “optics 1212”) for directing light of first light source 1210 onto CIT 110 within system 1200. Optics 1212 may include mirrors, prisms, lenses, and any other types of equipment which may be used for transforming light propagation. Optics 1212 may optionally include controllable components for changing properties of light such as propagation direction, focusing properties, optical wavefront of the light beam directed toward the CIT 110 but this is not necessarily so. Some examples for optics 1212 (and any other optics discussed below with respect to any part of the electromagnetic spectrum) include: motorized optics, deformable mirrors, piezoelectric actuators, optical modulators, optical isolators, lenses, mirrors, fiber optics, phase shifters, optical windows and pellicles. It is noted that while optics 1212 is illustrated in the diagrams as assembled together with light source 1210, this is not necessarily so, and optics 1212 may be positioned in any suitable location in system 1210. For example, optics 1212 (or parts thereof) may be positioned between the MLM mirror of 1230 and the instantaneous interaction area.

FIG. 5D illustrate an example in which the rotating target carrier 1260 include empty spaces for short-wave light to pass through (e.g., implemented as a wheel with multiple spokes).

Optionally, ionizable target material may be applied to moving target carrier 1260 at one or more locations 1170 (e.g., by an injector 2230, as discussed above). It is noted that any combination of any one or more of the components discussed with respect to FIGS. 5A-5D may be incorporated into system 1200 (e.g., as exemplified in FIG. 3). Referring to the examples discussed with respect to FIGS. 5A-5D, it is noted that application of ionizable target material to different parts of a rotating target carrier 1260 may be performed at different locations, such as at the center (e.g., using spin coating techniques), on or near the edge of target carrier 1260, or in intermediate locations 1170.

FIGS. 5-7 illustrate examples in which the moving target carrier 1260 moves in a plane which is not perpendicular to the illumination symmetry axis, and may be parallel thereto (or, closer to being parallel to that axis than perpendicular thereto). Such moving target carrier may move in rotational fashion (e.g., FIGS. 5 and 6), or linearly (at least at the area around area 1180 and/or 1190). Moving the target carrier 1260 in a plane positioned in such an angle with respect to the light source may be used for various reasons, such as geometrical reasons, and reducing the blocking of SWR by target carrier 1260.

As exemplified in FIGS. 5 and 6, the moving target carrier 1260 may scoop, attract, or otherwise collect ionizable target material (whether liquid, solid or a combination of the two) from ionizable target material reservoir 2210. Such way of collecting may also be implemented by a conveyer belt target carrier 1260 or any other type of target carrier 1260.

It is noted that optics 1230 may be designed to direct SWR away from the symmetry axis of illumination (e.g., using off-axis mirrors, grazing incidence mirrors), e.g., to resolve geometrical constrains and to improve SWR collection rate, which may be hampered by target carrier 1260 or by other components of the system.

Referring to all the optional variations of system 1200, it is noted that one or more heat removal mechanisms, systems and/or techniques may be implemented, in order to discard heat generated by heated target 110, target carrier 1260 and/or other components of system 1200 (e.g., as result of light of the at least one light source 1210).

Referring to systems 1200 in which target carrier 1260 is a rotating wheel or tube rotating about an axis perpendicular to the illumination symmetry axis (e.g., FIGS. 6A and 6B), it is noted that:
a. Laser can come from single angle or multiple angles.
b. Laser can hit either inner side or outer side of hollow wheel.
c. the collector of SWR can take several forms.

It is noted that system 1200 (as well as systems 200, 1200′, and 1200″) may include a vacuum chamber in which the interaction between light and ionizable target material (of the CIT) takes place. Vacuum chamber may be implemented in order to prevent blocking of the generated SWR by any air molecules or contaminants present in the environment. Vacuum chamber may be utilized to ensure unimpeded transmission of the generated extreme UV radiation by removing any potential obstructions. Any combination of one or more of the components of system 1200 (or 200, 1200′, 1200″ respectively) discussed above may be positioned within the vacuum chamber during operation of the respective system, as well as other components of the systems which were not discussed. It is noted that the other parts of the system may optionally also operate in vacuum. For example, vacuum may also be needed for focusing the laser, in order to prevent ionizing of the air by the laser before reaching the target, resulting in distortion to the light beam by the ionized air (plasma) which may hinder reaching a desired intensity on the target.

It is noted that systems 1200, 1200′, and 1200″ below (as well as system 200 above) may be implemented in a wide range of sizes and dimensions, e.g., depending on the desired power output of the system. In some nonlimiting examples which may be suitable for systems with power output of 0.2-10 KW, a size of the vacuum chamber in which the ionization takes places may be between ½-30 m. A size of an MLM mirror inside such a system (if implemented) may be for example between 1-500 cm, similar to a diameter of a rotating disk target carrier 1260 (if implemented). A thickness of the ionizable target matter of the CIT at the instantaneous interaction area may be, for example, between 1 μm and 1,000 μm. However, much narrower CITs may be implemented (e.g., as narrow as 50 nm), as well as much wider CITs (e.g., if being ionized directly out of a reservoir).

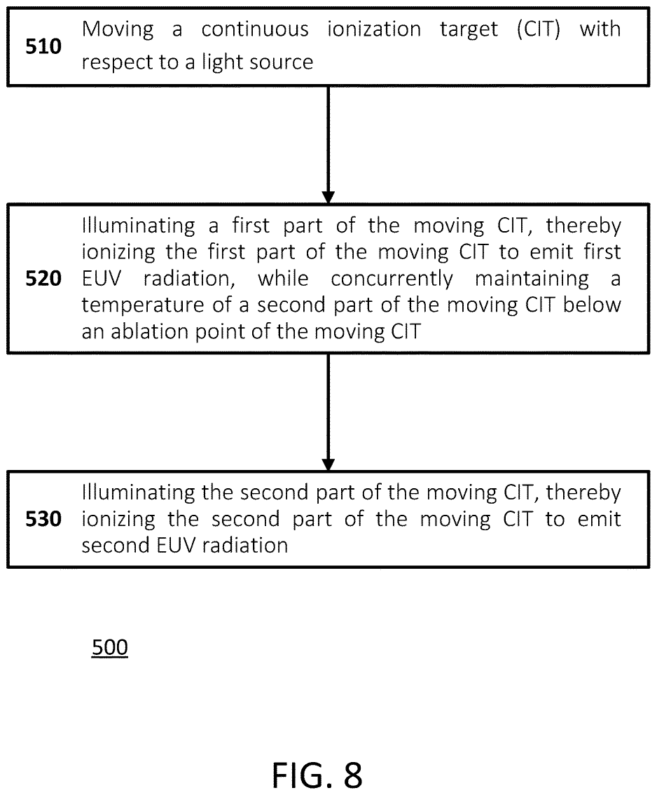

FIG. 8 is a flow chart illustrating an example of method 500, in accordance with the presently disclosed subject matter. Method 500 is a method for generating SWR, such as (but not limited to) extreme ultraviolet (EUV) radiation. Referring to the examples set forth with respect to the previous drawings, method 500 may optionally be executed by system 1200. Any variation, option, embodiment, or implementation discussed with respect to system 1200 may be applied to method 500 (e.g., as a method step), mutatis mutandis.

Step 510 of method 500 includes moving a CIT with respect to a light source. Referring to the examples set forth with respect to the previous drawings, step 510 may be executed by target carrier 1260 and/or motor 1270.

Step 520 includes illuminating a first part of the moving CIT, thereby ionizing the first part of the moving ionization target to emit first SWR, while a temperature of a second part of the moving CIT is concurrently maintained (actively or passively) below an ablation point of the moving CIT (optionally also below its vaporization point and/or ionization point, i.e., at a solid state and/or at a liquid state).

Step 530 of method 500 is executed after the ionization of the first part at step 520, and includes illuminating the second part of the moving CIT, thereby ionizing the second part of the moving CIT to emit second SWR.

Steps 520 and 530 are executed while the moving of step 510 is carried out.

Optionally, method 500 may include continuously emitting light toward the moving CIT, where the first part of the moving CIT and the second part of the moving CIT are both ionized during the continuous light emission. In such a case, the first SWR and the second SWR are parts of continuous SWR emitted from ionized parts of the CIT.

Optionally, method 500 may be executed such that the first part is ionized while positioned at a static ionization location of an SWR machine and the second part is ionized at a later time while positioned at the static ionization location of the SWR machine. In such a case, an area of the static ionization location may be at least 5 times smaller than a surface area of the CIT.

Optionally, method 500 may be executed such that the illuminating of the first part and the illuminating of the second part have a maximal ionizing illumination area on the CIT that is at least 5 times smaller than a surface area of the CIT.

Optionally, method 500 may be executed such that the maximal ionizing illumination area is at least 5 times smaller than a surface area of parts of the CIT which are ionized by a continuous light which ionizes the first part and the second part.

Optionally, method 500 may be executed such that the illuminating includes illuminating the first part and illuminating the second part while a velocity of the first part of the CIT and of the second part of the CIT exceeds 100 m/s.

Optionally, method 500 may be executed such that the moving of the CIT with respect to a light source is facilitated by moving a solid target carrier which concurrently supports at least the first part and the second part of the moving CIT.

Optionally, method 500 may be executed such that the moving of the solid target carrier comprises rotating the solid target carrier at angular velocity that exceeds 1,000 revolutions per minute ( RPM). For example, the implemented angular velocities may be exceeding 1,000 RPM, exceeding 5,000 RPM, exceeding 10,000 RPM, exceeding 20,000 RPM, exceeding 100,000 RPM, exceeding 200,000 RPM, and so on, depending on the requirements of the specific implementation.

Optionally, method 500 may include propelling ionizable target material onto the moving solid target carrier for forming the moving CIT.

Optionally, method 500 may include collecting of ionizable target material by the moving solid target carrier out of an ionizable target material reservoir, for forming the moving CIT. For example, the ionizable target material reservoir may store ionizable target material at a liquid state.

Optionally, method 500 may include collecting the first SWR and the second SWR and directing the first SWR and the second SWR toward a lithography object used in lithography manufacturing of computer chips.

Some of the reasons in which moving continuous target 110 might be preferred over droplets or other mass limited or microscopic targets in an EUV system include:
a. Great degree of control over shape of the ionizable area at the time of ionization. Target and/or target carrier can be designed and/or premanufactured accordingly. This allows great control over the shape of the target and more options for materials used. For example, target shape can benefit the laser plasma interaction and increase the conversion efficiency.
b. Target shape can be optimized for the specific interaction. For the specific wavelength of the laser (e.g., ~1 μm in oppose to ~10 μm), for the target material and the desired emitted radiation wavelength.
c. The spatial continuousness of CIT 110 which is brought by target carrier 1260 to the ionization location defined by the light sources 1210 and associated optics 1210, means that there is very little variation in the location of ionization at different times, which yields a high brightness of the source area.
d. Utilization of target carrier 1260 and/or continuous moving target 110 with suitable design can allow higher ionization rate of the system, since ionized areas are less affected by expansion of previous ionized areas, thus allowing higher target density and higher ionization rate and thus higher output power of the SWR with respect to the droplet generation scheme.
e. Utilization of target carrier 1260 and/or continuous moving target 110 with suitable design can reduce the need for an ongoing monitoring of the target position during CLD.
f. Allows to work with a continuous or QCW laser instead of a pulsed one. That is the biggest advantage. Since CW laser technology is much more efficient in making lasers with high average power, greater reliability, and lower costs than pulsed lasers.

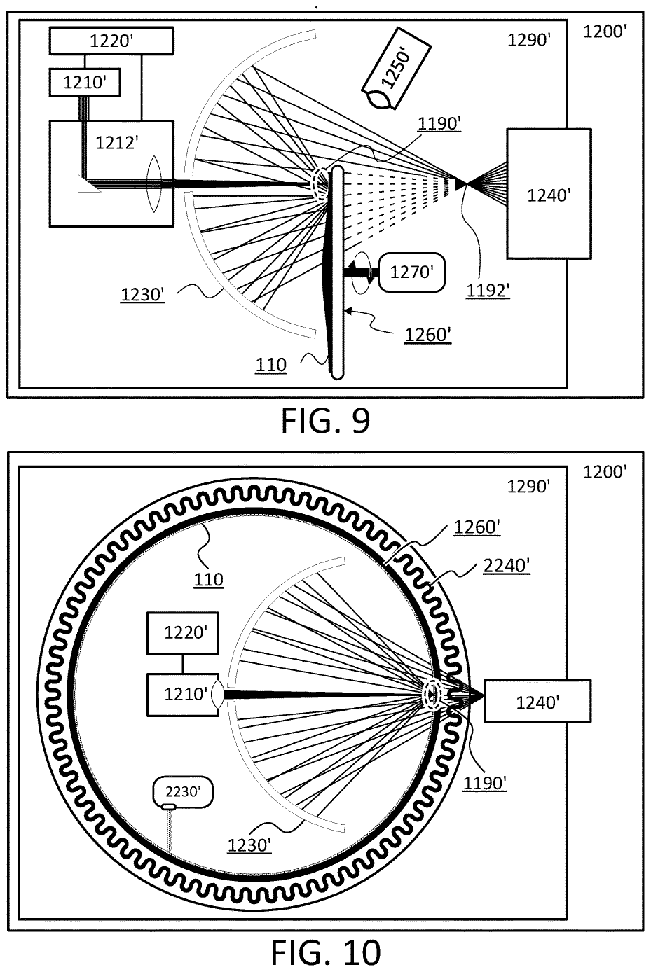

FIGS. 9 and 10 illustrate schematic diagrams of short-wave radiation systems 1200′ in accordance with examples of the disclosed subject matter. Short-wave radiation system 1200′ (also referred to as “Short-wave system 1200′”, “EUV system 1200′” and “system 1200′”) is designed for generating short-wave radiation, and includes at least optics 1230′ (represented by an optional MLM mirror) and at least one light source 1210′. It is noted that optionally, system 1200′ may be a variation of system 200 and/or a variation of system 1200 and/or a variation of system 1200″, with the ionization targets of system 1200′ being rather larger continuous targets 110 whose parts are ionized sequentially, either by short pulses or over longer exposures to the ionizing illumination (of the at least one light source). Any component, group of components, or interaction between components that is discussed with respect to system 200 may be incorporated, mutatis mutandis, to system 1200′. Any component, group of components, or interaction between components that is discussed with respect to system 1200 may be incorporated, mutatis mutandis, to system 1200′. Any component, group of components, or interaction between components that is discussed with respect to system 1200″ may be incorporated, mutatis mutandis, to system 1200′. Components of system 1200 whose reference signs (also known as “reference numbers” or “reference numerals”) begin with the digit “1” and which have a counterpart in system 200 without the leading digit “1” and without the apostrophe (e.g., light source 1210′ and light source 210) may be a variation of that corresponding component of system 200 even if not explicitly stated, and any discussion above pertaining to such a component of system 200 is also applicable (optionally as a variation or alternative) to the corresponding component of system 1200, mutatis mutandis. Components of system 1200′ whose reference signs (also known as “reference numbers” or “reference numerals”) have a counterpart in system 1200 without the apostrophe (e.g., light source 1210′ and light source 1210) or in system 1200″ with two apostrophes may be a variation of that corresponding component of system 1200 and/or system 1200″, even if not explicitly stated, and any discussion above pertaining to such a component of system 1200 and/or system 1200″ is also applicable (optionally as a variation or alternative) to the corresponding component of system 1200′, mutatis mutandis.

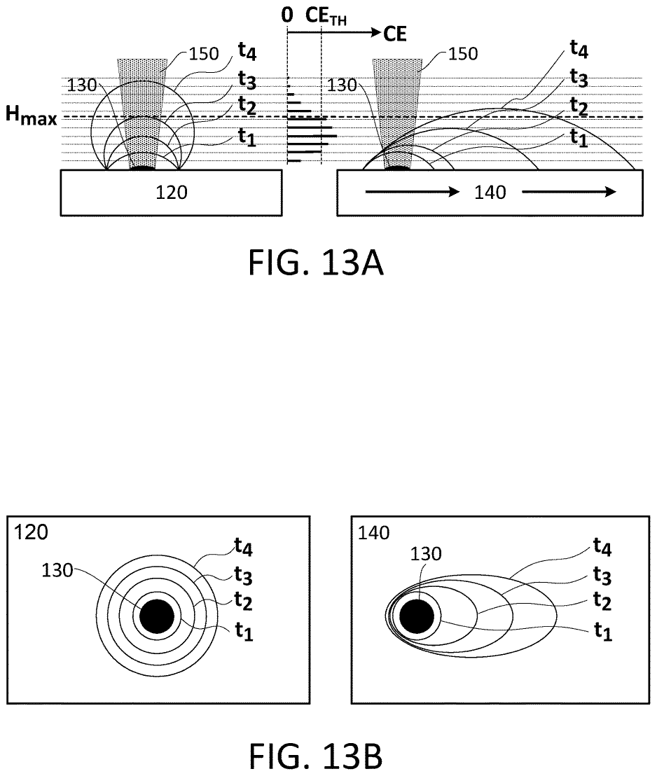

SWR system 1200′ utilizes one or more light sources (e.g., lasers) which are characterized by especially long continuous illumination times when compared with the light sources used in many industrial SWR machines used for mass production silicon chip lithography, for example. The one or more light sources 1210′ of system 1200′ may be a continuous-wave (CW) lasers, quasi-CW (QCW) lasers offering long continuous pulses (e.g., longer than 50 μs), or any sort of pulsed lasers which can emit continuous laser illumination at an operational power level (sufficient to ionize target material) for durations of 500 ns or more. Moving the ionizable target material with respect to such a light source at high velocities (e.g., over 100 m/s) means that the emitted light is continuously presented with new ionizable material to ionize (in order to emit SWR), while in the same time parts of a continuous ionization target (CIT) 110 which were heated by the illumination are being moved away, enabling the generated heat to be cooled down elsewhere, without interfering with the ionization process. Moving the ionizable target material with respect to such a light source at high velocities (e.g., over 100 m/s) also mitigates blocking of SWR by a cloud of low-density plasma that is generated as a result of ionization, as the dynamics of plasma expansion depend on the velocity of ionized target material (e.g., as discussed below with respect to FIGS. 13A and 13B).

As discussed above (e.g., with respect to the examples of FIGS. 5A-5D), the area of CIT 110 which is ionized in one continuous illumination of the CIT by the at least one light source 1210′ is much larger than an instantaneous interaction area of the at least one light source 1210′ on CIT 110 in which light of the light source interacts with the CIT to generate plasma. The instantaneous interaction area is the maximal area of CIT 110 which can be ionized by the at least one light source 1210′ without moving CIT 110 with respect to the at least one light source 1210′. While not necessarily so, the size of the instantaneous interaction area may be between 50% and 200% of the spot size of the at least one light source 1210′ on CIT 110 during ionization.

System 1200′ includes one or more light sources 1210′ that are collectively operable to continuously emit light for a continuous lighting duration (CLD) that is at least 500 nanoseconds long toward a CIT that is moving with respect to the at least one light source. The term “continuous lighting duration” pertains to a measure of time during which the intensity of illumination by the at least one light source suffices to continuously ionize and excite ionizable target material of CIT 110 to emit SWR at the ionization location (e.g., on a target carrier 1260′) without ceasing ionization for more than 100 ns. For example, the illumination intensity level sufficient for ionizing and exciting tin at the plane of the target is greater than 1.109 watts per cm 2. It is noted that while most of the discussion pertains to moving CIT 110 with respect to stationary light source (or stationary light source) 1210′, it is possible to implement system 1200′ with moving light sources 1210′ or with optics for rotating the illumination of a stationary light source, mutatis mutandis. In such cases, CIT 110 may be either stationary or moving.

The illumination by the at least one light source 1210′ during the CLD results in gradually ionizing (during the CLD) a continuous area of CIT 110 in a continuous manner, resulting in emittance by ionized parts of the CIT of continuous SWR during the CLD. An example of such a continuous area is area 114 discussed with respect to the examples of FIG. 4, and 5A-5D. The continuous area of the CIT is larger than an instantaneous interaction area projected by the at least one light source on the CIT 110 at any given moment (e.g., by at least one order of magnitude). The continuous area of the CIT is larger than an illuminated area projected by the at least one light source on the CIT 110 at any given moment (e.g., by at least one order of magnitude). The term “illuminated area” pertains to a part of the CIT which is illuminated by light emitted by the at least one light source 1210 at a given moment, while the term “instantaneous interaction area” pertains to an area of the CIT which, at a given moment, emits SWR as a result of the instantaneously cast light on the illuminated area. While these sizes are closely related, they are not identical, and may vary by a nonnegligible factor. In the discussion of the herein discussed systems and methods, any condition of the system which is phrased with respect to the instantaneous interaction area could also be applied in some implementations of the systems and method with respect to the illuminated area, mutatis mutandis. An ionization of the continuous area includes gradually ionizing over time of a surface area of CIT 110 without leaving unionized areas between different parts of the continuous area. The term “continuous SWR” pertains to SWR which has continuous non-zero amplitude for an unbroken duration of time, e.g., for the entire CLD, during which the SWR emission is not stopped for any duration longer than 100 ns.

Referring to systems 1200 and 1200′, as well as to methods 500 and 600, it is noted that the CLD is associated with the spatial profile of plasma generated as a result of being hit with the light source illumination. For example, the CLD may be substantially longer than the time it takes the plasma spatial profile, and hence the SWR emission, to reach a steady state. As discussed below in greater detail, the spatial profile of the plasma (and correspondingly, the resulting SWR emission), may be regulated by fast motion of the ionization target with respect to the light source. It is noted that the term “steady state” does not necessarily means a temporally uniform SWR emission, but rather a continuous generation of plasma, forming a continuous presence of plasma cloud around the instantaneous interaction area. Requiring the CLD to be longer than the time of reaching a steady state in a given system 1200 or 1200′ defines, in turn, a minimal size of the CIT (given the spot size and velocity). Under such requirements, the CIT have to include a continuous ionization target material in a size which is at least sufficient to pass through the instantaneous interaction area during a CLD which is sufficiently long to permit steady state plasma dynamics. Such systems do not have to be in a steady state in each moment, but rather this criterion poses minimal requirements of pulse duration. Optionally, systems 1200 and/or 1200′ may implement a CLD which permits reaching a steady state of the plasma dynamics, as discussed in this paragraph. It should be noted that the term “spot size” may pertain to a measure of an area (corresponding to the formerly discussed “illuminated area”). It is noted that while some people use the term “spot size” to pertain to a diameter of a circular spot of illumination (e.g., of a laser light source), any person who is of skill in the art would find understanding these alternative ways of looking at the magnitude of illumination useful, and would have no issues alternating between area and distance as useful metric.

As aforementioned, system 1200′ may include additional components (or corresponding component) discussed with respect to the system above. By way of example, system 1200′ further includes optics 1230′ (represented by an optional MLM mirror) which can direct the continuous SWR toward a designated beam direction (e.g., toward intermediate focus of the SWR system, or its output optics). It is noted that like in the system above, the directed SWR does not necessarily include all the SWR generated as a result of the ionization. It is noted that implementation of MLM mirror for the collection of the SWR provides higher efficiency, which when combined with continuous SWR short-wave emission may be used to achieve high output SWR power (e.g., over 100Watt), as discussed in greater detail throughout the application.

It is noted that optionally, system 1200′ (and especially the one or more light sources 1210′) may repeatedly illuminate different continuous areas of CIT 110 at different times, wherein in each of those instances the duration of illumination exceeds a CLD minimal threshold which is longer than 500 ns. Optionally, system 1200′ (and especially the one or more light sources 1210′) may repeatedly illuminate different continuous areas of CIT 110 at different times, wherein in each of those instances the plasma spatial profile of generated plasma reaches a steady state. Some examples of CLD minimal threshold which may be selected, depending on the operational parameters of the systems, include: between 500-1,000 ns, between 1-5 μs, between 5-10 μs, between 10-50 μs, between 50-500 μs, between 0.5-5ms, or longer than 5 ms (e.g., CW illumination, QCW illumination). By comparison, many prior art EUV generation systems used much shorter illumination durations, such as 1-2 ns pulses. Furthermore, many prior art EUV generation systems used shorter illumination duration which are insufficient for reaching a steady state plasma spatial profile. It is noted that each of the one or more CLDs of system 1200′ may be of somewhat varying durations, e.g., between 500-1,000 ns, between 1-5 μs, between 5-10 μs, between 10-50 μs, between 50-500 μs, between 0.5-5ms, or longer than 5 ms (e.g., CW illumination). In some cases (e.g., depending on the type of light sources 1210′ used), the at least one light source 1210′ may be incapable of (or prevented from) emitting pulses shorter than a minimal threshold (e.g., 500 ns, 1 μs, 10 μs), but this is not necessarily so. In many prior art EUV generation systems the target does not move substantially during the pulse, in comparison to moving many times the size of focal spot during the CLD at the disclosed systems.

The ratio between the areas of the continuous area of the CIT 110 (ionized by a single continuous light emission) and the area of the instantaneous interaction area projected by the at least one light source may differ, depending on various operational considerations (e.g., CLD, velocity of CIT 110). In some cases, that ratio may be between 2-5, between 5-10, between 10-100, between 100-1,000, or larger. The ratio may be larger than one order of magnitude, larger than two orders of magnitude, larger than three orders of magnitude, or even more. The size of the instantaneous interaction area may also vary, e.g., between 10-100 μm², 100-1,000 μm², 1,000-10,000 μm², 5,000-50,000 μm², or larger. The size of the continuous area may also vary, e.g., between 100-1,000 μm², between 1,000-10,000 μm², between 10,000-100,000 μm², or larger (possibly very large, in the case of prolonged CW illumination). The linear velocity of CIT 110 measured in the instantaneous interaction location of system 1210′ may also vary depending on various operation factors (e.g., required SWR output, heat dissipation capabilities, size of laser focal spot), such as between 100-500 m/s, between 0.5-2 km/s, between 2-10 km/s, or more. Optionally, system 1200′ may include a movable target carrier which is operable to propel the continuous area of the CIT at such velocities within any of those ranges (e.g., velocities that exceed 500 m/s) during the CLD. This may be achieved, for example, by rotating a movable target carrier at angular velocity that exceeds 1,000 revolutions per minute ( RPM), such as between 15-50 Hz, 50-100 Hz, 100-500 Hz, or higher. The linear or angular velocity of CIT 110 may be selected based on various factors, such as desired output, heat dissipation needs, reducing the effects of the plasma cloud (or larger ejecta) ejected from the ionization area (which is drifting as a result of the movement of CIT 110).

As mentioned above, different types of light sources which are capable of emitting CW, QCW, or light pulses which are longer than 500 ns may be used as light sources 1210′. For example, each light source 1210′ out of the at least one light source 1210′ may be a solid-state fiber laser (e.g., a diode pumped solid-state fiber laser) which is operable to emit continuous-wave (CW) or quasi-continuous-wave (QCW) laser illumination, such that a combined peak power of all of the at least one light source exceeds 10 KW for the entire CLD of at least 500 ns. Optionally, each light source 1210′ out of the at least one light source 1210′ is a multi-Kilowatt class solid-state fiber laser operable to emit continuous-wave (CW) or quasi continuous-wave (QCW).

Other types of lasers may be used (e.g., non-fiber solid-state lasers). It is noted that CW or QCW lasers can generate high average power illumination which simply does not exist in pulsed laser, and with better energetical efficiency from wall to light in the original laser. The proposed systems 1200 and 1200′ are capable of utilizing CW or QCW with long CLD, which are not suitable to many prior art SWR generation system. For example, SWR output of systems 1200 and 1200′ may be measured in hundreds of Watts.

Optionally, light source 1210′ may be a solid-state fiber laser (e.g., a diode pumped solid-state fiber laser) implementing coherent beam combining (CBC) between multiple fiber laser modules. The beams of the individual fiber laser modules of such a light source 1210′ are combined to obtain a single beam having correspondingly higher power and with similar beam quality, thus having an increased radiance (brightness). Such a coherent beam combining may also preserve the spectral bandwidth of the individual modules. Any suitable technique of CBC may be used, such as side-by-side combining (tiled aperture) techniques and filled-aperture techniques.

While many prior art SWR system prioritize conversion efficiency of the light source(s) power to output SWR power, some implementations of system 1200′ may reach significantly lower laser-to-SWR conversion efficiency (e.g., between 1-1.5%). Such lower laser-to-SWR conversion efficiency may result, for example, from ejecta and from plasma cloud forming around the ionization area, partially blocking the light source illumination and/or the generated SWR. Other causes may include, for example, using solid state laser with ~1-2 μm laser wavelength instead of a gas laser such as CO₂ lase with ~10 μm wavelength. The utilization of longer illumination durations may be used to offset the reduced laser to SWR conversion efficiency, and to enable generation of high power SWR output (e.g., hundreds of Watts worth). It is further noted that utilization of different types of light sources when compared to prior art system (e.g., solid-state lasers or fiber lasers, compared to pulsed gas laser) may enable utilization of light sources with improved electric optical efficiency (between the electricity supplied to light source 1210′ and its optical output) and higher average output optical power, further improving the overall efficiency (electricity to SWR output) of system 1200′ as well as the average output power (e.g. above 500 Watt).

By way of example, system 1200′ may include solid-state lasers (or other types of light source) having an electric-to-optical efficiency higher than 5%, higher than 15%, higher that 30%. System 1200′ (as well as system 1200) may also utilize light sources having different wavelength than prior art high-power SWR systems. For example, the one or more light sources 1210′ may output illumination having wavelength of about 1 μm, while common industrially available prior art SWR system utilize illumination having wavelength of about 10 μm. Thus, system 1200′ may optionally utilize short-wave laser (e.g., ~1 μm) and still output high power SWR. In comparison to system 1200′, implementing CW or QCW lasers in prior art SWR systems (in cases in which it is at all possible) may result in significantly reduced SWR output (e.g., due to the mostly impenetrable plasma cloud which would be created), or in other inefficiencies (e.g., if droplet targets are used, with relatively large spaces between any two droplets). However, as aforementioned, system 1200′ benefits from using relatively longer illumination periods. Optionally, the at least one light source 1210′ may be a laser assembly which comprises a plurality of solid-state lasers, collectively operating to provide the required illumination power. Optionally, the required illumination output of such a light source 1210′ may be achieved using only some of the individual solid-state lasers (e.g., by 90% of the individual modules). This way, if one or few laser modules of the light sources are defective in any way, other modules may replace them almost instantly, and the defective modules may be replaced or repaired without having to stop the operation of system 1200′ until the repair is completed.

Optionally, system 1200′ is operable to maintain temperatures of at least a half of the continuous area of the CIT below an ablation point of the moving CIT concurrently to the ionization of other parts of the continuous area by the at least one light source. The maintaining of pre-ionized parts of the continuous areas below ablation point may require dedicated active cooling and/or sufficiently fast velocity of the CIT, as well as other measures if needed.

While not necessarily so, the instantaneous interaction area of system 1200′ may be static during at least the CLD with respect to the at least one light source, wherein the at least one light source is operable to ionize each part of the continuous area of the CIT when the respective part is positioned at the static instantaneous interaction area.

Optionally, system 1200′ may include a movable solid target carrier that is operable to concurrently support (partly or fully) at least the continuous area of the CIT. In such cases, system 1200′ may also include a motor for moving the movable solid target carrier in order to move at least the continuous area with respect to the at least one light source 1210′. The moving of the CIT with respect to the at least one light source 1210′ keeps bringing cool ionizable matter for ionization in the ionization area, while removing extremely hot parts of the CIT heated by the illumination energy for cooling elsewhere.

If a moving (e.g., rotating) solid target carrier 1260′ is implemented (e.g., as discussed above with respect to target carrier 1260), ionizable target material may be applied to it in different ways. For example, system 1200′ may include at least one injector 2230′ which is operable to propel ionizable target material onto the moving solid target carrier 1260′ for forming the moving CIT 110. This may include applying spin coating of ionizable target material (e.g., tin) onto solid target carrier 1260′. The rotation of solid target carrier 1260′ may move the ionizable target material away toward the circumference of the rotating target carrier (e.g., disc, ring), from which it can be collected and cooled elsewhere. Another way (out of the many possible ways) for replenishing ionizable target material to the solid target carrier 1260′ is by having the moving solid target carrier collect ionizable target material out of an ionizable target material reservoir, for forming the moving CIT (e.g., as discussed with respect to FIG. 6B). It is worth noting that the shape of CIT 110 may change with time during the CLD (e.g., due to irregularities in replenishing the ionizable target material).

Similarly to system 1200, system 1200′ may optionally include optics for collecting the continuous SWR and for directing the continuously collected SWR toward a lithography object used in lithography manufacturing of computer chips.

As aforementioned, system 1200′ (as well as system 1200) may include one or more cooling mechanism 2240′ (e.g., a heat sink, as exemplified in FIG. 10) for cooling ionizable target material of the CIT during the CLD. The CIT ionizable target material may be part of CIT 110 at the time of the cooling, but this is not necessarily so (e.g., it could be ionizable target material removed from target carrier 1260′ and/or prior to injection onto target carrier 1260′). Any suitable type of cooling mechanism may be used, whether passive (e.g., heatsink) or active. Optionally, system 1200′ (as well as system 1200) may include one or more cooling mechanisms 2240′ (e.g., a heat sink, as exemplified in FIG. 10) for cooling target carrier 1260′.

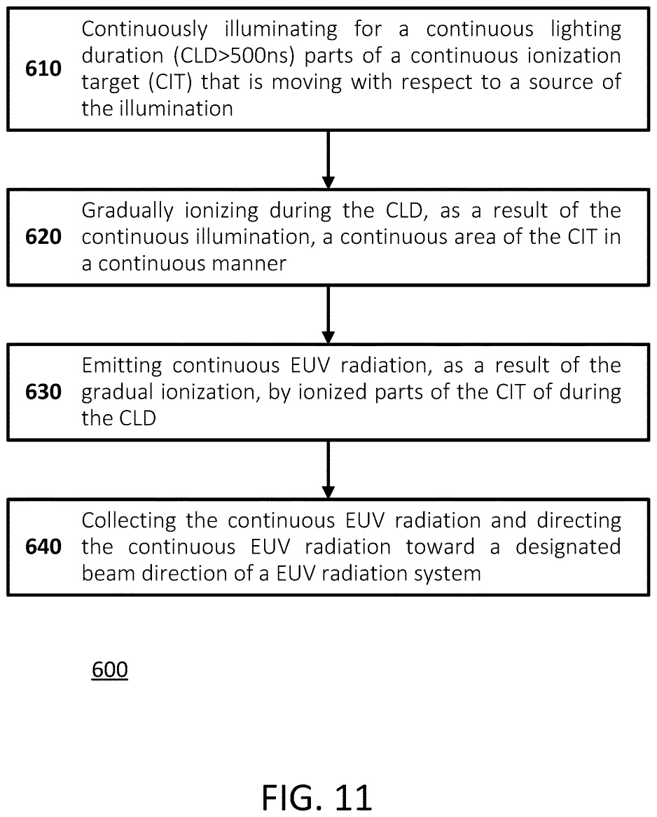

FIG. 11 is a flow chart illustrating an example of method 600, in accordance with the presently disclosed subject matter. Method 600 is a method for generating SWR, such as (but not limited to) extreme ultraviolet (EUV) radiation. Referring to the examples set forth with respect to the previous drawings, method 600 may optionally be executed by system 1200 and/or by system 1200′. Any variation, option, embodiment, or implementation discussed with respect to systems 1200 and 1200′ may be applied to method 600 (e.g., as a method step), mutatis mutandis. Furthermore, any step or combination of steps discussed above with respect to method 500 may optionally be incorporated into method 600, mutatis mutandis.

Step 610 of method 600 includes continuously illuminating for a continuous lighting duration (CLD) parts of a continuous ionization target (CIT) that is moving with respect to a source of the illumination, wherein the CLD is longer than 500 nanoseconds. Referring to the examples of the previous diagrams, step 610 may be executed by light source(s) 1210′, optionally in cooperation with controller 1220′.

Step 620 of method 600 includes gradually ionizing during the CLD, as a result of the continuous illumination, a continuous area of the CIT in a continuous

Step 630 of method 600 includes emitting continuous SWR, as a result of the gradual ionization, by ionized parts of the CIT of during the CLD.

The continuous area of the CIT in method 600 is at least one order of magnitude larger than an instantaneous interaction area created by the continuous illumination projected on the CIT at any given moment during the CLD.

The ratio between the areas of the continuous area of the CIT (ionized by a single continuous light emission) and the area of an instantaneous interaction area (created by the continuous illumination projected on the CIT at any given moment during the CLD) may differ, depending on various operational considerations. In some cases, that ratio may be between 2-5, between 5-10, between 10-100, between 100-1,000, or larger. The ratio may be larger than one order of magnitude, larger than two orders of magnitude, larger than three orders of magnitude, or even more. The size of the continuous area may also vary, e.g., between 100-1,000 μm², between 1,000-10,000 μm², between 10,000-100,000 μm2, or larger.

Optionally, method 600 may also include step 640 of collecting the continuous SWR and directing the continuous SWR toward a designated beam direction of a SWR system (e.g., output optics or intermediate focus thereof, if any). Referring to the examples set forth with respect to the previous drawings, step 640 may be executed by optics 1230′ and 1240′.

Optionally, the continuous illumination is executed by at least one solid-state fiber laser operable to emit continuous-wave (CW) or quasi-continuous-wave (QCW) laser illumination, such that a combined power of all of the at least one light source exceeds 10 KW for the entire CLD of at least 0.5 μs.

Optionally, method 600 may include maintaining temperatures of at least a half of the continuous area of the CIT below an ablation point of the moving CIT concurrently to the ionization of other parts of the continuous area.

Optionally, method 600 may include continuously moving different parts of the CIT into and out of a static instantaneous interaction area during the CLD, and ionizing each part of the continuous area when the respective part is positioned at the static instantaneous interaction area. Such a static area may be static with respect to outward optics of the respective SWR system.

Optionally, method 600 may include moving a movable solid target carrier that supports the continuous area of the CIT, thereby moving the continuous area with respect to a source of the illumination. Optionally, the moving may include rotating the movable solid target carrier at angular velocity that exceeds 1,000 revolutions per minute ( RPM). For example, the implemented angular velocities may be exceeding 1,000 RPM, exceeding 5,000 RPM, exceeding 10,000 RPM, exceeding 20,000 RPM, exceeding 100,000 RPM, exceeding 200,000 RPM, and so on, depending on the requirements of the specific implementation. Optionally, the moving may result in moving the continuous area of the CIT at velocities that exceed 100 m/s, exceed 500 m/s, exceed 1000 m/s, exceed 1500m (and so on) during the CLD. The linear velocity of the CIT (as measured in the instantaneous interaction location) may vary depending on various operation factors (e.g., required SWR output, heat dissipation capabilities, output power of the laser, focal spot size), such as between 100-500 m/s, between 0.5-2 km/s, between 2-10 km/s, or more. Optionally, the moving may include rotating the movable target carrier at angular velocity that exceeds 1,000 revolutions per minute ( RPM), such as between 15-50 Hz, 50-100 Hz, 100-500 Hz, or higher.

Optionally, method 600 may include propelling liquid ionizable target material onto the moving solid target carrier, thereby forming the moving CIT. Optionally, method 600 may include propelling solid ionizable target material onto the moving solid target carrier, thereby forming the moving CIT. Ionizable target material in combination of phases (e.g., solid and liquid, liquid and gas) may also be used.

Optionally, method 600 may include collecting by the moving solid target carrier ionizable target material out of an ionizable target material reservoir, thereby forming the moving CIT.

Optionally, method 600 may include collecting continuous SWR and directing the continuous SWR toward a lithography object used in lithography manufacturing of computer chips.

Optionally, method 600 may include cooling at least part of the continuous target carrier during the CLD. Optionally, method 600 may include cooling at least part of ionizable target material of the CIT during the CLD. Optionally, method 600 may include cooling during the CLD at least a part of at least one cooled object selected from a group consisting of: ionizable target material of the CIT and a movable solid target carrier that supports the continuous area of the CIT. It is noted that such cooling may also be executed in other times during the operation (e.g., between pulses if pulsed scheme is used).

FIG. 12A is a schematic chart in which curve 902 represents conversion efficiency of SWR emission resulting from ionization of stationary ionizable material for different durations, in accordance with examples of the presently disclosed subject matter. The abscissa of the chart indicates the duration of illumination of a pulse toward a stationary ionizable target (e.g., pulse duration), and the ordinate of the chart indicates the optical conversion efficiency of illumination hitting the ionization target (e.g., by the at least one light source of system 1200 or 1200′) to SWR resulting from turning of ionizable target material to plasma. Given a desired conversion efficiency (denoted CE_{TH}), there is a minimal illumination duration (denoted tₘᵢₙ) required until the target is sufficiently heated and excited to start emitting SWR in sufficient amount. For durations shorter than tₘᵢₙ the conversion efficiently is low since a large fraction of the pulse energy goes into initial ionization and a smaller fraction goes into exciting and heating the plasma to the needed degree of excitation temperature. In addition, sufficient plasma density gradients are not evolved yet, so the illumination beam (e.g., laser) interacts with a very thin layer of plasma leading to poor absorption of the laser in the plasma target. In addition, a substantial part of the laser energy goes into the initial ionization of the target. Longer duration of illumination provides more time in which the target can be heated, but also more time for a cloud of plasma and ejecta to be formed. As the illumination duration increases, the size and density of the resulting cloud of plasma and the ejecta increases, which in turn causes an increased absorption of SW radiation, and reduced optical conversion efficiency of the optical illumination beam (e.g., laser) into SW radiation, thus resulting in lower overall conversion efficiency.

When the illumination duration toward the target exceeds a maximal illumination duration (denoted tₘₐₓ), the conversion efficiency falls below the desired threshold, and eventually diminishes to substantially zero. For pulse durations longer than tₘₐₓ, the plasma has much time to expand, leading to laser absorption (and SW radiation generation) deep in the plasma. The generated SW radiation is being absorbed on its way out leading to poor overall conversion efficiency. A maximal optical conversion efficiency (denoted CEₘₐₓ) is achieved at a specific duration whose length is between tₘᵢₙ and tₘₐₓ.

It is noted that the actual physics of SW radiation generation from a stationary ionization target are more complicated, of course. For example, spatial effects of plasma expansion are different at elongated laser exposure when compared to short time exposure, as well as other effects. It is further noted that the interaction of light, plasma, and SW radiation strongly depends on wavelength of incoming illumination as well as on the wavelength of the desired SW radiation (assuming only small part of the SW spectrum is being collected). Both incoming illumination (e.g., laser) absorption and ionization mechanisms are wavelength depend, and the critical penetration depth of the incoming illumination (e.g., laser) into the plasma depends on the wavelength of the incoming illumination (e.g., laser). In general, it is expected that for shorter wavelength, this curve will shift toward shorter times. One optional way of determining the values of tₘᵢₙ and tₘₐₓ for a given wavelength is by experimental methods. The specific tₘᵢₙ and tₘₐₓ depend on various factors such as a material of the ionization target, the power of the illuminating light source, the size of the ablation area, and the required conversion efficiency. As an illustrative example only, in some SWR emitting systems based on prior art technology and for light sources emitting 1.064 μm, tₘᵢₙ may be about 1 ns while tₘₐₓ may be about 10-100 ns or 100-1000 ns.

FIG. 12B is a schematic chart in which curve 904 represents conversion efficiency of SWR emission resulting from ionization of moving targets for different durations, in accordance with examples of the presently disclosed subject matter. The abscissa of the chart indicates the duration of illumination of a pulse toward a stationary ionizable target (e.g., pulse duration), and the ordinate of the chart indicates the optical conversion efficiency of illumination hitting the ionization target (e.g., by the at least one light source of system 1200 or 1200′) to SWR resulting from turning of ionizable target material to plasma. It is noted that, for sake of clarity and as this is a very schematic chart, minor changes with respect to curve 902 in the early stages of illumination are not reflected graphically. The movement of CIT 110 with respect to the light source maintains the CE high; one possible explanation for this effect is that this movement results in lesser obstruction of radiation by the aforementioned cloud of plasma and ejecta (as is further discussed, for example, with respect to FIGS. 13A and 13B), and therefore the conversion efficiency of radiation at the static ionization location from which SWR is collected remains above the desired conversion efficiency (CE_{TH}). The transient time from the beginning of illumination until the SWR emission reaches a steady state (which may possibly fluctuate to a certain degree) is denoted TSTD in FIG. 12B). This effect is represented in the difference progression represented by curves 904 and 906 (the latter, represented by a dashed line, corresponds to the relevant part of curve 902 of FIG. 12A). While there may be a gradual decline in the conversion efficiency from the maximal conversion efficiency, the constant mobilization of the CIT by the system maintains the conversion efficiency above the required threshold. Optionally, while the overall illumination time exceeds (possibly by one, several, or many orders of magnitudes) tₘₐₓ, each point on the target is exposed to less than tₘₐₓ.

Reverting to the at least one light source 1210, it is noted that while light source 1210 may be a CW light source (e.g., a CW laser, a CW laser array, a CW LED light), light source 1210 may also be a non-CW source, e.g., as discussed above. For example, light source 1200 may be a QCW light source. In cases in which light source 1210 is not a CW light source, it may implement different duty cycles in different implementations of the invention. For example, a duty cycle of light source 1210 may be of at least 1:20. For example, a duty cycle of light source 1210 may be between 1:20-1:10, between 1:15-1:5, between 1:10-1:5, between 1:6-1:2, between 1:3-1:2, between 1:2-9:10, etc. It is noted that light sources 1210 with such duty cycles may be implemented in system 1200 regardless of the duration of each CLD (e.g., be it longer or shorter than 500 ns). By way of nonlimiting comparison, many prior art systems which generate SWR utilized pulsed light sources (e.g., pulsed laser) having considerably lower duty cycles like ≤1:200, ≤1:500, ≤1:1,000, etc.

Using such duty cycles (e.g., within any one of the optional ranges suggested in the previous paragraph with respect to light source 1210) means that system 1200 generates EUV in comparatively expanded parts of the operation time of system 1200. For example, using light sources with duty cycle of 1:20 would allow system 1200 to emit SWR in 3 minutes of each hour, compared with only 18 seconds of every hour in duty cycle of 1:200. Thus, even if a conversion efficiency of system 1200 (denoted CE_{CO}) is somewhat lower than can be achieved with short-pulse-low-duty cycle systems (even CEₘₐₓ, for the sake of discussion), integration of the output over the much longer parts of each minute and each hour may be used to yield high output of SWR. That is, the average power output facilitated by the operation of the systems and methods discussed above benefits from the use of such larger duty cycles, enabled by the teaching of the presently disclosed systems and methods.

As mentioned above, the systems and methods discussed above may benefit from such duty cycles (e.g., ≥1:20) regardless of the duration of the CLD. According to an aspect of the invention, there is disclosed a high duty-cycle SWR system that includes:
a. at least one light source, collectively operable to repeatedly emit light, at a duty cycle which exceeds 1:20 (or even 1:10, 1:5, 1:2, in some of the possible embodiments), for a plurality of continuous lighting durations (CLDs) toward a continuous ionization target (CIT) that is moving with respect to the at least one light source, thereby gradually ionizing during each CLD a continuous area of the CIT in a continuous manner, resulting in emittance by ionized parts of the CIT of continuous SWR during the respective CLD; and
b. optics, for directing the plurality of continuous SWR emissions toward a designated beam direction of the SWR system.

The high duty-cycle SWR system may implement at least one of the following requirements:
a. The continuous area of the CIT during each CLD is at least one order of magnitude larger (or even two or three orders of magnitude) than an illuminated area projected by the at least one light source on the CIT at any given moment during the respective CLD.
b. During each CLD no point of the CIT is being illuminated for longer than 100 ns (or even 50 ns, 30 ns, or 10 ns, in some of the possible embodiments).

It is noted that each of the features, characteristics, structures, variations, features, relationships, etc., discussed above with respect to any one of systems 200, 1200, 1200′, and 1200″ and/or any one or more of the components of these systems may be implemented, mutatis mutandis, also for this high duty-cycle SWR system. Such details are not repeated here in the interest of concision.

According to an aspect of the invention, there is disclosed a method for generating SWR at high duty-cycle. That method includes:
a. Repeatedly illuminating, at a duty cycle which exceeds 1:20 (or even 1:10, 1:5, 1:2, in some of the possible embodiments), in a series of continuous lighting durations (CLDs) parts of a continuous ionization target (CIT) that is moving with respect to a source of the illumination.
b. Gradually ionizing during each of the CLDs, as a result of the continuous illumination, a continuous area of the CIT in a continuous manner.
c. Emitting during each of the CLDs continuous SWR, as a result of the gradual ionization, by ionized parts of the CIT that are ionized during the CLD.

The aforementioned method for generating SWR at high duty-cycle may implement at least one of the following requirements:
a. The continuous area of the CIT during each CLD is at least one order of magnitude larger than an illuminated area created by the continuous illumination projected on the CIT at any given moment during that CLD.
b. During each CLD no point of the CIT is being illuminated for longer than 100 ns (or even 50 ns, 30 ns, or 10 ns, in some of the possible embodiments).

It is noted that each of the steps, processes, characteristics, variations, relationships, etc., discussed above with respect to any one of methods 500 and 600, and/or any one or more of the steps of these methods, may be implemented, mutatis mutandis, also for this method for high duty-cycle SWR generation. Such details are not repeated here in the interest of concision.

FIG. 13A is a schematic side view illustration representing sizes of plasma clouds emitted from a stationary ionization target 120 (represented in the illustration in a nonlimiting way as a wide target) and from a moving ionization target 140 (which can be, for example, continuous ionization target 110) when illuminated by light (e.g., laser), at different times after the onset of the illumination, in accordance with examples of the presently disclosed subject matter. Referring to stationary ionization target 120, when illuminated by light at different times, t₁ is substantially equal to tₘᵢₙ of FIG. 12, t₂ is an intermediary time whose duration is between tₘᵢₙ and tₘₐₓ, t₃ is substantially equal to tₘₐₓ, and t₄ is substantially longer than tₘₐₓ. At the left side of the diagram, an optical conversion efficiency comparable to the conversion efficiency threshold is shown for each size of plasma cloud (represented by its size along a perpendicular to the illuminated surface of the target). The illumination light spot is denoted 130. The plasma cloud has a gradient of density such that the plasma is denser close to the target surface and is more diluted as the distance from the surface is increased. Efficient light absorption and SW radiation is emitted mostly from a plasma “critical layer”, a density layer within the plasma cloud, where the plasma is sufficiently dense. The external part of the plasma cloud is too dilute to absorb light and emit sufficient SW radiation but can still absorb or scatter SW radiation that travels through it. As can be seen, only between t₁ and t₃ sufficient SW radiation is emitted toward the collection optics (not shown). Between these times the dilute external part of the plasma cloud is still small, so the SW radiation emitted from a region closer to the target surface can sufficiently escape the plasma cloud. As the laser illumination gets longer, more target material is ionized, the plasma cloud expands, and said dilute external part of the cloud becomes thicker, absorbing or scattering more of the SW radiation before it escapes the plasma cloud. As represented by t₄, illumination of ionization target 120 for longer durations would result in an extended low-density part of the plasma cloud, significant absorption and scattering of the SW radiation while it travels throughout through the low-density plasma and ultimately, significantly diminished conversion efficiency. Therefore, many prior art systems aim for pulse duration between tₘᵢₙ and tₘₐₓ for as high a conversion efficiency as possible, e.g., around duration t_{CEmax} which yields the best conversion efficiency (e.g., around 1.5-100 ns for some prior art systems).

In the illustrated examples, the incoming illumination is represented by light beam 150, for the sake of explanation only. As can be seen, the motion of moving ionization target 140 reshapes the spatio-temporal profile of the plasma cloud relative to the illumination light spot 130. The motion of the ionization target 140 material is translated to the motion of the ionized material and other ejecta, which in turn is diverted away from the illumination spot 130 in the direction of motion of the target 140. While at the beginning of the illumination (e.g., at time t₁ from beginning of illumination) the plasma cloud is still small, as the illumination continues the plasma cloud expands in an asymmetric shape, elongated in the direction of motion of the target (e.g., as illustrated in the top view diagram of the corresponding FIG. 13B). As a result, at time t₄ and in later times the size of the plasma cloud at the region under the illumination beam 130, is still lower than Hₘₐₓ, meaning that at the time t₄ the conversion efficiency is still higher than CE_{TH}. The maximal perpendicular depth of plasma cloud which permits transmission of sufficient SW radiation from stationary ionization target 120 is denoted Hₘₐₓ. In other words, as a result of the initial motion of the ionization target material 140, the CE remains above CEₜₕ, even for times that are longer than tₘₐₓ, in contrast to the case with a stationary target 120.

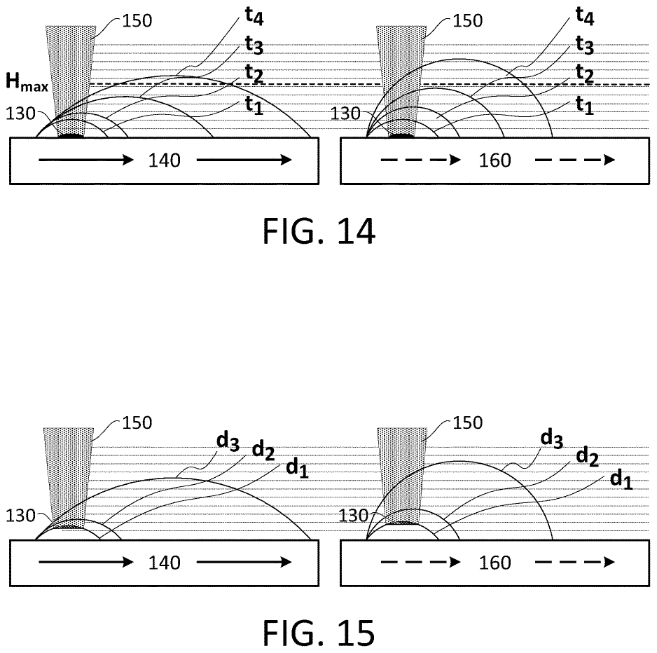

FIG. 14 is a schematic illustration representing sizes of plasma clouds emitted from a faster moving ionization target 140 (which can be, for example, continuous ionization target 110) and a slower moving ionization target 160 (which can be, for example, continuous ionization target 110) at four different times after the onset of the light illumination, in accordance with examples of the presently disclosed subject matter. As can be seen, since ionization target 160 moves in a slower velocity when compared to ionization target 140, at the later times after the onset of illumination (e.g., t₄ and longer), the displacement of the plasma cloud is insufficient to bring the size of the ejecta and plasma cloud under the illumination beam 150, to be below Hₘₐₓ, and therefore the conversion efficiency is lower than the aforementioned threshold CE_{TH}. However, in the case of the faster moving ionization target 140, the velocity of target 140 is sufficient to displace the plasma cloud and the ejecta such that at long times after the onset of illumination (e.g. t₄ or longer) the size of the plasma cloud under the illumination beam 150 is still below Hₘₐₓ, maintaining the conversion efficiency above CE_{TH}, resulting in similar overall CE as in the case of a pulsed illumination with the duration t₂. In fact, this creates a steady state condition in which the CE is no longer depended on the duration of illumination at all, allowing to utilize CW laser or QSW laser in contrast to prior art scheme which requires short pulses for effective SWR generation. The longer duration of continuous illumination (CLD) in systems 1200 and 1200′ may yield similar conversion efficiency of illuminated light to SW radiation when compared to pulsed illumination having light pulses with duration between tₘᵢₙ and tₘₐₓ, in the same respective system.

FIG. 15 is a schematic illustration representing densities of steady state plasma clouds emitted from targets moving at different velocities, in accordance with examples of the presently disclosed subject matter. At sufficiently long times after the onset of the illumination light, for a uniform target under fixed illumination, the spatial density profile of the plasma at the vicinity of the illumination beam spot will cease to evolve in time and reach a steady state. The lines denoted dl represent surfaces of substantially equal density d1, which is the critical density for laser penetration beyond which laser does not penetrate. The lines denoted d2 represent surfaces of substantially equal density d2. The lines denoted d3 represent surfaces of substantially equal density d3. Density d1>d2>d3. In the illustrated example, absorption of the illumination light in the plasma that results with efficient emission of short short-wave radiation only occurs where the plasma density is between d1 and d2. At densities lower than d2 the plasma absorbs and scatters short-wave radiation that travels through it, but does not emit short-wave radiation efficiently when exposed to the illumination beam. Densities lower than d3 are negligible, not absorbing nor emitting any substantial amounts of relevant radiation. FIG. 15 shows a comparison of the spatial profile of the plasma cloud between a faster moving ionization target 140 (which can be, for example, continuous ionization target 110) and a slower moving ionization target 160 (which can be, for example, continuous ionization target 110). It is noted that the dimensions and scale of the diagrams of FIGS. 14 and 15 are illustrative only, and that the targets of FIG. 15 may move at different velocities than the targets of FIG. 14. As illustrated in FIG. 15, the external dilute part of the plasma (where the density is between d2 and d3) is moved further away from the illumination spot on the faster moving target 140, while the inner region of the plasma cloud, where the density is between d1 and d2, is still found under the illumination beam spot. This leads to less absorption and scattering of the short-wave radiation in the dilute plasma in the region between d2 and d3 (when compared with the slower moving target), before it escapes the plasma cloud altogether. As a result, at a steady state the slower moving target 160 does not emit short-wave radiation with conversion efficiency higher than CE_{TH}. However, the steady state spatial density profile of the plasma in the case of the faster moving target 140 is such that the conversion efficiency remains continuously above CE_{TH}, even when the laser illumination is substantially infinite (that is, much longer than the time it takes the plasma cloud to reach the steady state).

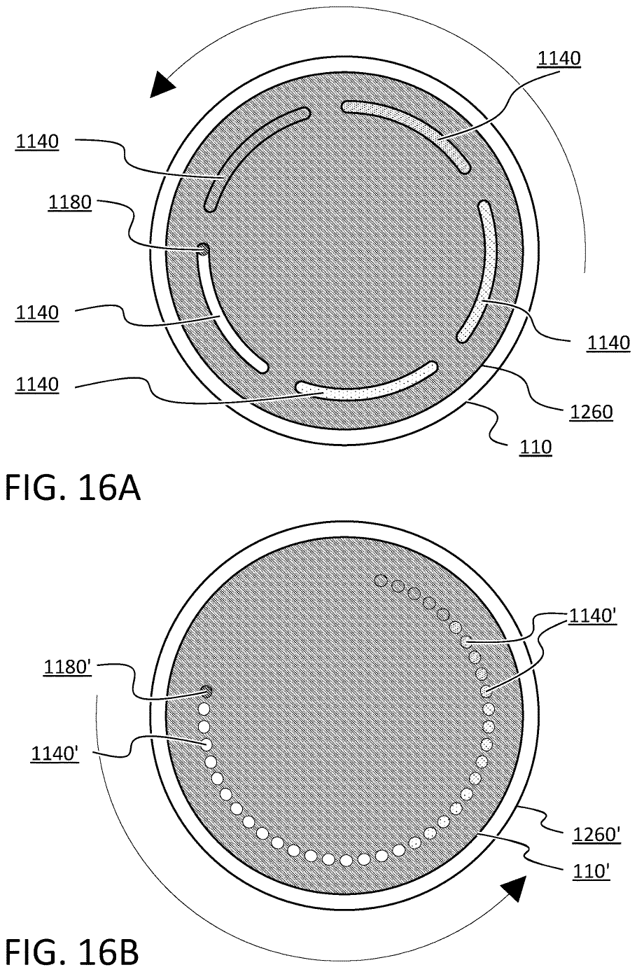

FIGS. 16A and 16B offer a schematic comparison between a continuous illumination (e.g., exceeding 500 ns) emitted toward a moving target, as discussed above with respect to the present invention, and much shorter illumination periods (e.g., shorter than 50 ns) toward a moving target, which may be implemented under very different operational rationales (e.g., in order to replenish ionizable target material). Similar reference numbers are used in FIG. 16B in which short illumination duration are used (shorter than 100 ns, e.g., shorter than 50 ns, e.g., about 10-30 ns) to those used with respect to system 200, with an additional apostrophe that indicates that these are separate targets used in separate systems under different conditions (e.g., different target velocity, different illumination durations, and so on), and under different operational rationale. In the example of FIG. 16A, each continuous area 1140 of CIT 110 that is being illuminated by a single continuous illumination pulse (e.g., a nonbreaking or a substantially nonbreaking illumination pulse) is at least one order of magnitude larger (e.g., at least ×10 larger) than illuminated area 1180 that is being projected by the at least one light source on the CIT at any given moment during the CLD. By way of comparison, the corresponding area 1140′ of CIT 110′ that is being illuminated by each much-shorter illumination pulse (e.g., shorter than 30 ns) is much less significantly different in size than the corresponding illuminated area 1180′ that is being projected by the at least one light source on the CIT at any given moment during the CLD. For example, area 1140′ may be about 101%-105% of the instantaneously illuminated area 1180% (i.e., about 1%-5% larger), in comparison to 1000% difference in size of the corresponding areas of FIG. 16A. It is noted that while it might be theoretically possible to move CIT 110′ at much higher velocities, such velocities are in many cases impractical, expensive to implement, and/or countering to other incentive of system design (e.g., complicating handling of ejecta and debris). Moreover, such theoretical high velocities are not congruent with suggested rationales for implementing moving target in combination with short pulses (e.g., as discussed previously in this paragraph). An example of such rationale, replenishing of ionizable target material, is represented by the darkening of the areas 1140′ in the diagram, in positions corresponding to longer times passing since being illuminated by the illumination source. As exemplified in FIG. 16A, such rationale may also be implemented together with the teaching of the present invention. However, as exemplified with respect to FIG. 16B, the rationale of replenishing target material in itself does not require especially high velocities, and does not require prolonged illumination durations.

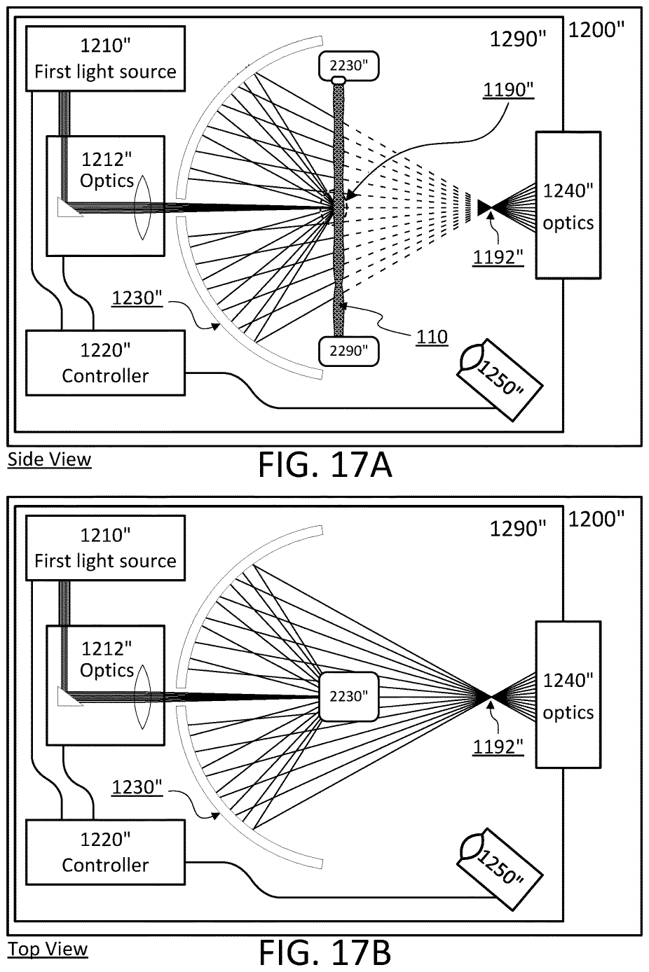

FIGS. 17A and 17B illustrate schematic diagrams of SWR systems 1200″ in accordance with examples of the disclosed subject matter. Short-wave radiation system 1200′ (also referred to as “Short-wave system 1200″”, “EUV system 1200″” and “system 1200″”) is designed for generating short-wave radiation. It is noted that optionally, system 1200″ may be a variation of any combination of any one or more of systems 200, 1200, and 1200′. Any component, group of components, or interaction between components that is discussed with respect to any one or more of systems 200, 1200, and 1200′ may be incorporated, mutatis mutandis, to system 1200″. Components of system 1200″ whose reference signs (also known as “reference numbers” or “reference numerals”) have a counterpart in the description of any one or more of systems 200, 1200, and 1200′ (as discussed above) may be a variation of that corresponding component of the respective system, even if not explicitly stated, and any discussion above pertaining to such a component of any one or more of systems 200, 1200 and/or 1200′ is also applicable (optionally as a variation or alternative) to the corresponding component of system 1200″, mutatis mutandis.

As exemplified in the illustrated example of FIGS. 17A and 17B (which offer perpendicular views of the same system), CIT 110 is not necessarily supported. More specifically, the illuminated part of CIT 110 and its vicinity do not have to be supported during illumination (and possibly neither in other times) in order for the disclosed systems to operate. That is, system 1200″ (as well as the other systems discussed above), does not need to include moving target carrier 1260 or any other means to support CIT 110. System 1200″ may, for example, utilize CITs 110 which are fluids (e.g., liquid, gas, or a combination thereof) whose movement does not result from that of a solid part of the system but rather from other sources source as gravity, pressurized injection, and so on. For example, CIT 110 may be a jet of fluid (e.g., a jet of gas, a jet of liquid) onto which focus light of one or more light sources 1200″ is directed in order to ionize parts of the jet over time, in the same location (denoted interaction area 1190″). Parts of the jetted material that are not ionized may continue their progression (e.g., using their existing momentum) and collected or otherwise disposed of at another location. For example, system 1200″ may include injector 2230″ for introducing a jet of ionizable target material toward interaction area 1190″ where parts of it can be ionized. For example, system 1200″ may include an end point 2290″ in which the fluid of ionizable target material of CIT 110 is collected or otherwise disposed of. By way of example, such an end point 2290″ may include a tank, a pump, a collector, etc. While a jet of fluid is an elongated target, it is also quite narrow in the other dimensions, and thus while it blocks SWR over a relatively elongated area (as demonstrated by the dashed SWR propagation paths in FIG. 17A), it does not obstruct SWR propagation in the rest of the area (as demonstrated by the continuous SWR propagation paths in FIG. 17B). It is also noted that a cylindrically symmetric jet of fluid is just one option to propel fluid ionizable material in the system, and any other suitable geometry may be used instead (e.g., a jet with elliptical cross section, a cascading screen of fluid, and so on).

It is noted that a thickness of such a jet may vary depending on various factors such as the material of the fluid, intensity of the light source, and so on. By way of a non-limiting example, the jet of fluid may have a thickness of 10 μm-2 mm. It is noted that a velocity of the fluid in such a jet may vary depending on various factors such as the material of the fluid, intensity of the light source, and so on. By way of a non-limiting example, the jet of fluid may have a velocity of 10-1000 m·sec⁻¹. In addition to, or as alternative of, thinking of the continuous area as an identifiable area of a plane or a surface, the continuous area may also be thought of, considering the fluid nature of CIT 110 in such cases, as an integration of the instantaneous illumination area over time. For example, in such cases the continuous area that is being ionized by the illumination pulse during the continuous lighting duration (CLD) may be defined more generally as [symbol] where [symbol] is the velocity of the target, [symbol] is the illumination spot size in the direction perpendicular to [symbol] and [symbol] is the pulse duration.

### NUMBERED EMBODIMENTS

In the following paragraphs, several non-limiting examples are discussed in concise manner. The following example may be variations of the systems and methods discussed above (with similarly named components having similar structure and/or functionality as those of the systems discussed above), and may also be understood as separate examples, which will be interpreted by a person who is of ordinarily skilled in the art in an expansive way, based on concepts discussed above.

Numbered embodiment 1 is of a SWR system, the system including: (a) at least one light source, collectively operable to emit light toward a continuous ionization target (CIT) that is moving with respect to the at least one light source, including: (i) illuminating a first part of the moving CIT, thereby ionizing the first part of the moving CIT to emit first SWR, while a temperature of a second part of the moving CIT is concurrently maintained below an ablation point of the moving CIT; and (ii) after the ionization of the first part, illuminating the second part of the moving CIT, thereby ionizing the second part of the moving CIT to emit second SWR; and (b) optics, for directing the first SWR and the second SWR toward a designated beam direction of the SWR system.

Numbered embodiment 2 includes the SWR system of numbered embodiment 1, wherein the at least one light source is operable to continuously emit light toward the moving CIT, sequentially ionizing parts of the moving CIT in a continuous manner between at least the first part and the second part, for emitting by ionized parts of the CIT a continuous SWR that includes the first SWR and the second SWR.

Numbered embodiment 3 includes the SWR system of any one of numbered embodiments 1 and 2, including a static ionization location positioned along at least one illumination cone of the at least one light source, wherein the at least one light source is operable to ionize the first part while positioned at the static ionization location and to ionize the second part at a later time while positioned at the static ionization location, wherein an area of the static ionization location is at least 5 times smaller than a surface area of the CIT.

Numbered embodiment 4 includes the SWR system of any one of numbered embodiments 1-3, wherein the at least one light source can concurrently ionize a maximal area of the CIT that is at least 5 times smaller than a surface area of the CIT.

Numbered embodiment 5 includes the SWR system of numbered embodiment 4, wherein the maximal area is at least 5 times smaller than a surface area of parts of the continuous CIT which are ionized by a continues light of the light source

Numbered embodiment 6 includes the SWR system of any one of numbered embodiments 1-5, further including a movable solid target carrier operable to concurrently support (partly or fully) at least the first part of the moving CIT and the second part of the moving CIT, and a motor for moving the movable solid target carrier in order to concurrently move at least the first part of the CIT and the second part of the CIT with respect to the at least one light source.

Numbered embodiment 7 includes the SWR system of numbered embodiment 6, wherein the movable target carrier is operable to rotate at angular velocity that exceeds 1,000 revolutions per minute ( RPM).

Numbered embodiment 8 includes the SWR system of numbered embodiment 6, wherein the wherein the movable target carrier is operable to propel the first part of the CIT and of the second part of the CIT to velocities that exceed 100 m/s when ionized by the at least one light source.

Numbered embodiment 9 includes the SWR system of any one of numbered embodiments 6-8, including at least one injector operable to propel ionizable target material onto the moving solid target carrier for forming the moving CIT.

Numbered embodiment 10 includes the SWR system of any one of numbered embodiments 6-8, wherein the moving solid target carrier is operable to collect ionizable target material out of an ionizable target material reservoir, for forming the moving CIT.

Numbered embodiment 11 includes the SWR system of any one of numbered embodiments 1-10, further including optics for collecting the first SWR and the second SWR and for directing the first SWR and the second SWR toward a lithography object used in lithography manufacturing of computer chips.

Numbered embodiment 12 includes a method for generating SWR, the method including: (a) moving a continuous ionization target (CIT) with respect to a light source; (b) illuminating a first part of the moving CIT, thereby ionizing the first part of the moving CIT to emit first SWR, while concurrently maintaining a temperature of a second part of the moving CIT below an ablation point of the moving CIT; and (c) after the ionization of the first part, illuminating the second part of the moving CIT, thereby ionizing the second part of the moving CIT to emit second SWR.

Numbered embodiment 13 includes the method of numbered embodiment 12, including continuously emitting light toward the moving CIT, wherein the first part of the moving CIT and the second part of the moving CIT are both ionized during the continuous light emission, wherein the first SWR and the second SWR are parts of continuous SWR emitted from ionized parts of the CIT.

Numbered embodiment 14 includes the method of any one of numbered embodiments 12 and 13, wherein the first part is ionized while positioned at a static ionization location of a SWR machine and the second part is ionized at a later time while positioned at the static ionization location of the SWR machine, wherein an area of the static ionization location is at least 5 times smaller than a surface area of the CIT.

Numbered embodiment 15 includes the method of any one of numbered embodiments 12-14, wherein the illuminating of the first part and the illuminating of the second part have a maximal ionizing illumination area on the CIT that is at least 5 times smaller than a surface area of the CIT.

Numbered embodiment 16 includes the method of numbered embodiment 12, method according to claim 15, wherein the maximal ionizing illumination area is at least 5 times smaller than a surface area of parts of the CIT which are ionized by a continues light which ionizes the first part and the second part.

Numbered embodiment 17 includes the method of any one of numbered embodiments 12-16, wherein the illuminating includes illuminating the first part and illuminating the second part while a velocity of the first part of the CIT and of the second part of the CIT exceeds 100 m/s.

Numbered embodiment 18 includes the method of any one of numbered embodiments 12-17, wherein the moving of the CIT with respect to a light source is facilitated by moving a solid target carrier which concurrently supports at least the first part and the second part of the moving CIT.

Numbered embodiment 19 includes the method of numbered embodiment 18, wherein the moving of the solid target carrier includes rotating the solid target carrier at angular velocity that exceeds 1,000 revolutions per minute ( RPM).

Numbered embodiment 20 includes the method of any one of numbered embodiments 18 and 19, including propelling ionizable target material onto the moving solid target carrier for forming the moving CIT.

Numbered embodiment 21 includes the method of any one of numbered embodiments 18 and 19, including collecting of ionizable target material by the moving solid target carrier out of an ionizable target material reservoir, for forming the moving CIT.

Numbered embodiment 22 includes the method of any one of numbered embodiments 12-21, any one of claims 1-10, further including collecting the first SWR and the second SWR and directing the first SWR and the second SWR toward a lithography object used in lithography manufacturing of computer chips.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention. It will be appreciated that the embodiments described above are cited by way of example, and various features thereof and combinations of these features can be varied and modified. While various embodiments have been shown and described, it will be understood that there is no intent to limit the invention by such disclosure, but rather, it is intended to cover all modifications and alternate constructions falling within the scope of the invention, as defined in the appended claims.

What is claimed is:

1. Short wave Radiation (SWR) system, the system comprising:
at least one light source, collectively operable to continuously emit light for a continuous lighting duration (CLD) that is at least 500 nanoseconds long toward a continuous ionization target (CIT) that is moving with respect to the at least one light source, thereby gradually ionizing during the CLD a continuous area of the CIT in a continuous manner, resulting in emittance by ionized parts of the CIT of continuous SWR during the CLD; wherein the continuous area of the CIT is at least one order of magnitude larger than an illuminated area projected by the at least one light source on the CIT at any given moment during the CLD; and
optics, for directing the continuous SWR toward a designated beam direction of the SWR system.

2. The SWR system according to claim 1, wherein the continuous area of the CIT is at least 10,000 μm².

3. The SWR system according to any one of claims 1 and 2, wherein each light source out of the at least one light source is a multi-Kilowatt class solid-state fiber laser operable to emit continuous-wave (CW) or quasi-continuous-wave (QCW).

4. The SWR system according to any one of claims 1-3, operable to maintain temperatures of at least a half of the continuous area of the CIT below an ablation point of the moving CIT concurrently to the ionization of other parts of the continuous area by the at least one light source.

5. The SWR system according to any one of claims 1-4, wherein an instantaneous interaction area is static during at least the CLD with respect to outward optics of the SWR system, wherein the at least one light source is operable to ionize each part of the continuous area of the CIT when the respective part is positioned at the static instantaneous interaction area.

6. The SWR system according to any one of claims 1-5, further comprising a movable solid target carrier operable to concurrently support at least the continuous area of the CIT, and a motor for moving the movable solid target carrier in order to move at least the continuous area with respect to the at least one light source.

7. The SWR system according to claim 6, wherein the movable solid target carrier is operable to rotate at angular velocity that exceeds 1,000 revolutions per minute ( RPM).

8. The SWR system according to claim 6, wherein the movable target carrier is operable to propel the continuous area of the CIT to velocities that exceed 500 m/s during the CLD.

9. The SWR system according to any one of claims 6-8, comprising at least one injector operable to propel ionizable target material onto the moving solid target carrier for forming the moving CIT.

10. The SWR system according to any one of claims 6-8, wherein the moving solid target carrier is operable to collect ionizable target material out of an ionizable target material reservoir, for forming the moving CIT.

11. The SWR system according to any one of claims 1-10, further comprising optics for collecting the continuous SWR and for directing the continuous SWR toward a lithography object used in lithography manufacturing of computer chips.

12. A method for generating Short Wave Radiation (SWR), the method comprising:
continuously illuminating for a continuous lighting duration (CLD) parts of a continuous ionization target (CIT) that is moving with respect to a source of the illumination, wherein the CLD is longer than 500 nanoseconds;
gradually ionizing during the CLD, as a result of the continuous illumination, a continuous area of the CIT in a continuous manner; and
emitting continuous SWR, as a result of the gradual ionization, by ionized parts of the CIT of during the CLD;
wherein the continuous area of the CIT is at least one order of magnitude larger than an illuminated area created by the continuous illumination projected on the CIT at any given moment during the CLD.

13. The method according to claim 12, wherein the continuous area of the CIT is at least 100 times larger than an instantaneous interaction area.

14. The method according to any one of claims 12 and 13, wherein the continuous illumination is executed by at least one multi-Kilowatt class solid-state fiber laser operable to emit continuous-wave (CW) or quasi-continuous-wave (QCW) laser.

15. The method according to any one of claims 12-14, comprising maintaining temperatures of at least a half of the continuous area of the CIT below an ablation point of the moving CIT concurrently to the ionization of other parts of the continuous area.

16. The method according to any one of claims 12-15, comprising continuously moving different parts of the CIT into and out of a static instantaneous interaction area during the CLD, and ionizing each part of the continuous area when the respective part is positioned at the static instantaneous interaction area.

17. The method according to any one of claims 12-16, further comprising moving a movable solid target carrier that supports the continuous area of the CIT, thereby moving the continuous area with respect to a source of the illumination.

18. The method according to claim 17, wherein the moving comprising rotating the movable solid target carrier at angular velocity that exceeds 1,000 revolutions per minute ( RPM).

19. The method according to claim 17, wherein the moving results in moving the continuous area of the CIT at velocities that exceed 500 m/s during the CLD.

20. The method according to any one of claims 17-19, comprising propelling liquid ionizable target material onto the moving solid target carrier, thereby forming the moving CIT.

21. The method according to any one of claims 17-19, comprising collecting by the moving solid target carrier ionizable target material out of an ionizable target material reservoir, thereby forming the moving CIT.

22. The method according to any one of claims 12-21, further comprising collecting continuous SWR and directing the continuous SWR toward a lithography object used in lithography manufacturing of computer chips.

23. The method according to any one of claims 12-22, comprising cooling during the CLD at least a part of at least one cooled object selected from a group consisting of: ionizable target material of the CIT and a movable solid target carrier that supports the continuous area of the CIT.
